(19) United States
(12) Patent Application Publication
(10) Pub. No.: US 2018/0201800 A1
(43) Pub. Date: Jul. 19, 2018

(54) NON-AQUEOUS INK COMPOSITIONS CONTAINING METALLOID NANOPARTICLES SUITABLE FOR USE IN ORGANIC ELECTRONICS

(71) Applicant: NISSAN CHEMICAL INDUSTRIES, LTD., Tokyo (JP)

(72) Inventors: Jing WANG, Gibsonia, PA (US); Elena SHEINA, Pittsburgh, PA (US); Robert SWISHER, Pittsburgh, PA (US); Floryan DECAMPO, Pittsburgh, PA (US); Carolyn SKILLMAN, Zelienople, PA (US); Sergey B. LI, Glenshaw, PA (US)

(21) Appl. No.: 15/743,580

(22) PCT Filed: Jul. 6, 2016
(86) PCT No.: PCT/US2016/041048

§ 371 Date: Jan. 10, 2018

Related U.S. Application Data
(60) Provisional application No. 62/194,000, filed on Jul. 17, 2015.

(51) Int. Cl. C09D 11/52; C09D 11/033; C09D 11/037; C09D 11/102; H01L 51/00

(52) U.S. Cl. CPC C09D 11/52; C09D 11/033; C09D 11/037; H01L 51/5088; H01L 51/0036; H01L 51/0003; C09D 11/102

(57) ABSTRACT

Described herein are non-aqueous ink compositions containing a polythiophene having a repeating unit complying with Formula (I) described below, one or more metalloid nanoparticles, and a liquid carrier having one or more organic solvents. The present disclosure also concerns the uses of such non-aqueous ink compositions, for example, in organic electronic devices. Formula (I) wherein R₁ and R₂ are each, independently, H, alkyl, fluoroalkyl, alkoxy, aryloxy, or —O—[Z—O]ₚ—Rₑ; wherein Z is an optionally halogenated hydrocarbylene group, p is equal to or greater than 1, and Rₑ is H, alkyl, fluoroalkyl, or aryl.

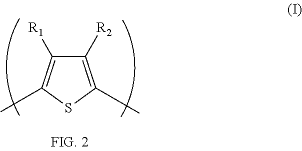

### CROSS REFERENCE TO RELATED APPLICATIONS

This application claims priority to U.S. Provisional Application No. 62/194,000, filed on Jul. 17, 2015, the entire content of which is explicitly incorporated herein by this reference.

### FIELD OF THE INVENTION

The present disclosure relates to a non-aqueous ink composition comprising a polythiophene polymer and metalloid nanoparticles, and uses thereof, for example, in organic electronic devices.

### BACKGROUND

Although useful advances are being made in energy saving devices such as, for example, organic-based organic light emitting diodes (OLEDs), polymer light emitting diodes (PLEDs), phosphorescent organic light emitting diodes (PHOLEDs), and organic photovoltaic devices (OPVs), further improvements are still needed in providing better materials processing and/or device performance for commercialization. For example, one promising type of material used in organic electronics is the conducting polymers including, for example, polythiophenes. However, problems can arise with polymers' purity, processability, and instability in their neutral and/or conductive states. Also, it is important to have very good control over the solubility of polymers utilized in alternating layers of various devices' architectures (e.g., orthogonal or alternating solubility properties among adjacent layers in particular device architecture). These layers, for example, also known as hole injection layers (HILs) and hole transport layers (HTLs), can present difficult problems in view of competing demands and the need for very thin, but high quality, films.

In a typical OLED device stack, the refractive index for most p-doped polymeric HILs is around 1.5, such as HILs comprising PEDOT:PSS, while the emissive materials generally have a refractive index that is substantially higher (1.7 or higher). As a result, additional total internal reflection occurs at EML/HIL (or HTL/HIL) and HIL/ITO interfaces, leading to reduced light extraction efficiency.

There is an ongoing unresolved need for a good platform system to control properties of hole injection and transport layers, such as solubility, thermal/chemical stability, and electronic energy levels, such as HOMO and LUMO, so that the compounds can be adapted for different applications and to function with different compounds, such as light emitting layers, photoactive layers, and electrodes. Good solubility, intractability, and thermal stability properties are important. Also of importance is the ability to tune HIL resistivity and HIL layer thickness while retaining high transparency, low absorptivity, low internal reflection, low operating voltage, within the OLED system, and prolonged lifetime, among other properties. The ability to formulate the system for a particular application and provide the required balance of such properties is also important.

### SUMMARY OF THE INVENTION

In a first aspect, the present disclosure relates to a non-aqueous ink composition comprising:
(a) a polythiophene comprising a repeating unit complying with formula (I)

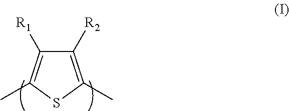

wherein R₁ and R₂ are each, independently, H, alkyl, fluoroalkyl, alkoxy, aryloxy, or —O—[Z—O]ₚ—Rₑ;
   wherein
      Z is an optionally halogenated hydrocarbylene group,
      p is equal to or greater than 1, and
      Rₑ is H, alkyl, fluoroalkyl, or aryl;
(b) one or more metalloid nanoparticles; and
(c) a liquid carrier comprising one or more organic solvents.

In a second aspect, the present disclosure relates to a process for forming a hole-carrying film, the process comprising:
1) coating a substrate with a non-aqueous ink composition described herein; and
2) annealing the coating on the substrate, thereby forming the hole-carrying film.

In a third aspect, the present disclosure relates to a hole-carrying film formed by the process described herein.

In a fourth aspect, the present disclosure relates to a device comprising the hole-carrying film described herein, wherein the device is an OLED, OPV, transistor, capacitor, sensor, transducer, drug release device, electrochromic device, or battery device.

An objective of the present invention is to provide the ability to tune electrical properties, thermal, and operational stability to unable increased lifetime, of HILs in a device comprising the compositions described herein.

Another objective of the present invention is to provide the ability to tune film thickness and retain high transparency or low absorbance in the visible spectrum (transmittance >90% T) in a device comprising the compositions described herein.

### BRIEF DESCRIPTION OF THE FIGURES

FIG. 1 shows the resistivity of films made from a base ink, free of SiO₂ nanoparticles, as a function of annealing temperature.

FIG. 2 shows the resistivities of films made from inventive NQ inks 6-8 as a function of annealing temperature.

FIG. 3 shows the thickness of the films made from inventive NQ inks 6-8 as a function of annealing temperature.

FIG. 4 shows thermal stability improvement in an HIL made from NQ ink 1 (DMSO based with SiO₂) vs. Base ink (DMSO based ink without SiO₂).

FIG. 5 shows voltage (hole injection) improvement in an HIL made from NQ ink 11 vs. an HIL made from NQ ink 12.

FIG. 6 shows plate-to-plate result variability improvement in an HIL made from NQ ink 10 vs. an HIL made from NQ ink 9.

### DETAILED DESCRIPTION

As used herein, the terms “a”, “an”, or “the” means “one or more” or “at least one” unless otherwise stated.

As used herein, the term “comprises” includes “consists essentially of” and “consists of.” The term “comprising” includes “consisting essentially of” and “consisting of.”

The phrase “free of” means that there is no external addition of the material modified by the phrase and that there is no detectable amount of the material that may be observed by analytical techniques known to the ordinarily-skilled artisan, such as, for example, gas or liquid chromatography, spectrophotometry, optical microscopy, and the like.

Throughout the present disclosure, various publications may be incorporated by reference. Should the meaning of any language in such publications incorporated by reference conflict with the meaning of the language of the present disclosure, the meaning of the language of the present disclosure shall take precedence, unless otherwise indicated.

As used herein, the terminology “(Cx-Cy)” in reference to an organic group, wherein x and y are each integers, means that the group may contain from x carbon atoms to y carbon atoms per group.

As used herein, the term “alkyl” means a monovalent straight or branched saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, 2-ethylhexyl, octyl, hexadecyl, octadecyl, eicosyl, behenyl, tricontyl, and tetracontyl.

As used herein, the term “fluoroalkyl” means an alkyl radical as defined herein, more typically a (C₁-C₄₀) alkyl radical that is substituted with one or more fluorine atoms.

Examples of fluoroalkyl groups include, for example, difluoromethyl, trifluoromethyl, perfluoroalkyl, 1H,1H,2H,2H-perfluorooctyl, perfluoroethyl, and —CH₂CF₃.

As used herein, the term “hydrocarbylene” means a divalent radical formed by removing two hydrogen atoms from a hydrocarbon, typically a (C₁-C₄₀) hydrocarbon. Hydrocarbylene groups may be straight, branched or cyclic, and may be saturated or unsaturated. Examples of hydrocarbylene groups include, but are not limited to, methylene, ethylene, 1-methylethylene, 1-phenylethylene, propylene, butylene, 1,2-benzene; 1,3-benzene; 1,4-benzene; and 2,6-naphthalene.

As used herein, the term “alkoxy” means a monovalent radical denoted as —O-alkyl, wherein the alkyl group is as defined herein. Examples of alkoxy groups, include, but are not limited to, methoxy, ethoxy, n-propoxy, isopropoxy, n-butoxy, isobutoxy, and tert-butoxy.

As used herein, the term “aryl” means a monovalent unsaturated hydrocarbon radical containing one or more six-membered carbon rings in which the unsaturation may be represented by three conjugated double bonds. Aryl radicals include monocyclic aryl and polycyclic aryl. Polycyclic aryl refers to a monovalent unsaturated hydrocarbon radical containing more than one six-membered carbon ring in which the unsaturation may be represented by three conjugated double bonds wherein adjacent rings may be linked to each other by one or more bonds or divalent bridging groups or may be fused together. Examples of aryl radicals include, but are not limited to, phenyl, anthracenyl, naphthyl, phenanthrenyl, fluorenyl, and pyrenyl.

As used herein, the term “aryloxy” means a monovalent radical denoted as —O-aryl, wherein the aryl group is as defined herein. Examples of aryloxy groups, include, but are not limited to, phenoxy, anthracenoxy, naphthoxy, phenanthrenoxy, and fluorenoxy.

Any substituent or radical described herein may optionally be substituted at one or more carbon atoms with one or more, same or different, substituents described herein. For instance, a hydrocarbylene group may be further substituted with an aryl group or an alkyl group. Any substituent or radical described herein may also optionally be substituted at one or more carbon atoms with one or more substituents selected from the group consisting of halogen, such as, for example, F, Cl, Br, and I; nitro (NO₂), cyano (CN), and hydroxy (OH).

As used herein, the term “hole carrier compound” refers to any compound that is capable of facilitating the movement of holes, i.e., positive charge carriers, and/or blocking the movement of electrons, for example, in an electronic device. Hole carrier compounds include compounds useful in layers (HTLs), hole injection layers (HILs) and electron blocking layers (EBLs) of electronic devices, typically organic electronic devices, such as, for example, organic light emitting devices.

As used herein, the term “doped” in reference to a hole carrier compound, for example, a polythiophene polymer, means that the hole carrier compound has undergone a chemical transformation, typically an oxidation or reduction reaction, more typically an oxidation reaction, facilitated by a dopant. As used herein, the term “dopant” refers to a substance that oxidizes or reduces, typically oxidizes, a hole carrier compound, for example, a polythiophene polymer. Herein, the process wherein a hole carrier compound undergoes a chemical transformation, typically an oxidation or reduction reaction, more typically an oxidation reaction, facilitated by a dopant is called a “doping reaction” or simply “doping”. Doping alters the properties of the polythiophene polymer, which properties may include, but may not be limited to, electrical properties, such as resistivity and work function, mechanical properties, and optical properties. In the course of a doping reaction, the hole carrier compound becomes charged, and the dopant, as a result of the doping reaction, becomes the oppositely-charged counterion for the doped hole carrier compound. As used herein, a substance must chemically react, oxidize or reduce, typically oxidize, a hole carrier compound to be referred to as a dopant. Substances that do not react with the hole carrier compound but may act as counterions are not considered dopants according to the present disclosure. Accordingly, the term “undoped” in reference to a hole carrier compound, for example a polythiophene polymer, means that the hole carrier compound has not undergone a doping reaction as described herein.

The present disclosure relates to a non-aqueous ink composition comprising:
(a) a polythiophene comprising a repeating unit complying with formula (I)

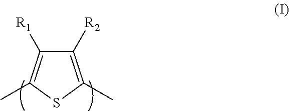

wherein R₁ and R₂ are each, independently, H, alkyl, fluoroalkyl, alkoxy, aryloxy, or —O—[Z—O]ₚ—Rₑ;
   wherein
      Z is an optionally halogenated hydrocarbylene group,
      p is equal to or greater than 1, and
      Rₑ is H, alkyl, fluoroalkyl, or aryl;
(b) one or more metalloid nanoparticles; and
(c) a liquid carrier comprising one or more organic solvents.

The polythiophene suitable for use according to the present disclosure comprises a repeating unit complying with formula (I)

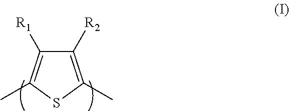

wherein R₁ and R₂ are each, independently, H, alkyl, fluoroalkyl, alkoxy, aryloxy, or —O—[Z—O]ₚ—Rₑ; wherein Z is an optionally halogenated hydrocarbylene group, p is equal to or greater than 1, and Rₑ is H, alkyl, fluoroalkyl, or aryl.

In an embodiment, R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d}, are each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

In an embodiment, R₁ is H and R₂ is other than H. In such an embodiment, the repeating unit is derived from a 3-substituted thiophene.

The polythiophene can be a regiorandom or a regioregular compound. Due to its asymmetrical structure, the polymerization of 3-substituted thiophenes produces a mixture of polythiophene structures containing three possible regiochemical linkages between repeat units. The three orientations available when two thiophene rings are joined are the 2,2′; 2,5′, and 5,5′ couplings. The 2,2′ (or head-to-head) coupling and the 5,5′ (or tail-to-tail) coupling are referred to as regiorandom couplings. In contrast, the 2,5′ (or head-to-tail) coupling is referred to as a regioregular coupling. The degree of regioregularity can be, for example, about 0 to 100%, or about 25 to 99.9%, or about 50 to 98%. Regioregularity may be determined by standard methods known to those of ordinary skill in the art, such as, for example, using NMR spectroscopy.

In an embodiment, the polythiophene is regioregular. In some embodiments, the regioregularity of the polythiophene can be at least about 85%, typically at least about 95%, more typically at least about 98%. In some embodiments, the degree of regioregularity can be at least about 70%, typically at least about 80%. In yet other embodiments, the regioregular polythiophene has a degree of regioregularity of at least about 90%, typically a degree of regioregularity of at least about 98%. 3-substituted thiophene monomers, including polymers derived from such monomers, are commercially-available or may be made by methods known to those of ordinary skill in the art. Synthetic methods, doping, and polymer characterization, including regioregular polythiophenes with side groups, is provided in, for example, U.S. Pat. No. 6,602,974 to McCullough et al. and U.S. Pat. No. 6,166,172 to McCullough et al.

In another embodiment, R₁ and R₂ are both other than H. In such an embodiment, the repeating unit is derived from a 3,4-disubstituted thiophene.

In an embodiment, R₁ and R₂ are each, independently, —O[C(RₐR_{b})—C(R_{c}R_{d})—O]ₚ—Rₑ, or —OR_{f}. In an embodiment, R₁ and R₂ are both —O[C(RₐR_{b})—C(R_{c}R_{d})—O]ₚ—Rₑ. R₁ and R₂ may be the same or different.

In an embodiment, each occurrence of Rₐ, R_{b}, R_{c}, and R_{d}, are each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

In an embodiment, R₁ and R₂ are each —O[CH₂—CH₂—O]ₚ—Rₑ. In an embodiment, R₁ and R₂ are each —O[CH(CH₃)—CH₂—O]ₚ—Rₑ.

In an embodiment, Rₑ is methyl, propyl, or butyl.

In an embodiment, the polythiophene comprises a repeating unit selected from the group consisting of

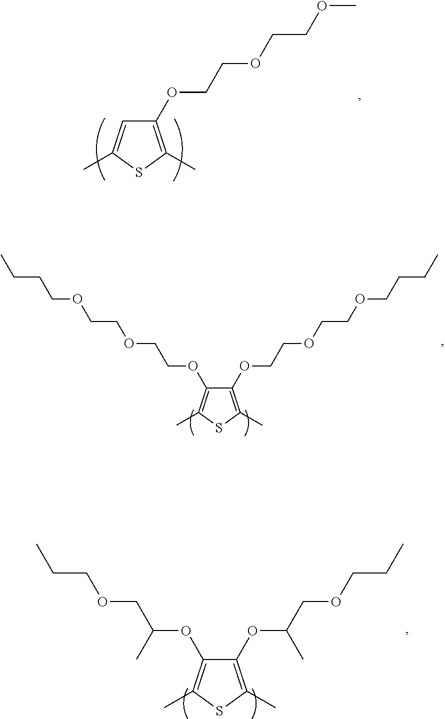

and combinations thereof.

It would be understood by the ordinarily-skilled artisan that the repeating unit

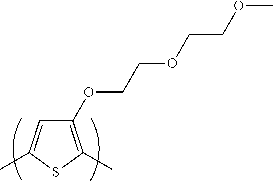

is derived from a monomer represented by the structure

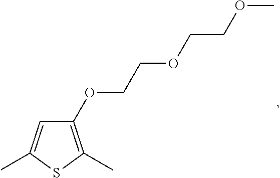

3-(2-(2-methoxyethoxy)ethoxy)thiophene [referred to herein as 3-MEET]; the repeating unit

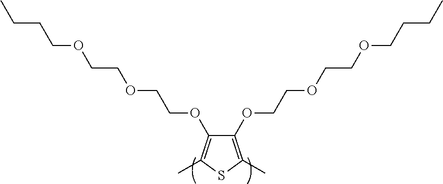

is derived from a monomer represented by the structure

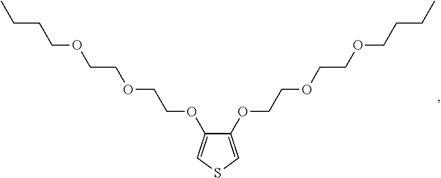 [SMILES: CCCCOCCOCCOc1cscc1OCCOCCOCCCC]

3,4-bis(2-(2-butoxyethoxy)ethoxy)thiophene [referred to herein as 3,4-diBEET]; and the repeating unit

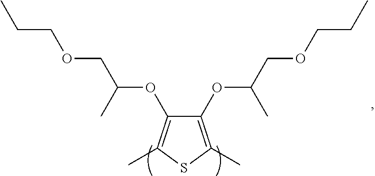

is derived from a monomer represented by the structure

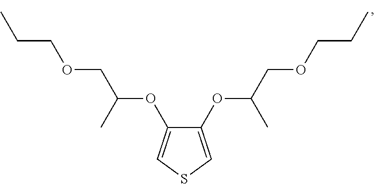 [SMILES: CCCOCC(C)Oc1cscc1OC(C)COCCC]

3,4-bis((1-propoxypropan-2-yl)oxy)thiophene [referred to herein as 3,4-diPPT].

3,4-disubstituted thiophene monomers, including polymers derived from such monomers, are commercially-available or may be made by methods known to those of ordinary skill in the art. For example, a 3,4-disubstituted thiophene monomer may be produced by reacting 3,4-dibromothiophene with the metal salt, typically sodium salt, of a compound given by the formula HO—[Z—O]ₚ—Rₑ or HOR_{f}, wherein Z, Rₑ, R_{f} and p are as defined herein.

The polymerization of 3,4-disubstituted thiophene monomers may be carried out by, first, brominating the 2 and 5 positions of the 3,4-disubstituted thiophene monomer to form the corresponding 2,5-dibromo derivative of the 3,4-disubstituted thiophene monomer. The polymer can then be obtained by GRIM (Grignard methathesis) polymerization of the 2,5-dibromo derivative of the 3,4-disubstituted thiophene in the presence of a nickel catalyst. Such a method is described, for example, in U.S. Pat. No. 8,865,025, the entirety of which is hereby incorporated by reference. Another known method of polymerizing thiophene monomers is by oxidative polymerization using organic non-metal containing oxidants, such as 2,3-dichloro-5,6-dicyano-1,4-benzoquinone (DDQ), or using a transition metal halide, such as, for example, iron(III) chloride, molybdenum(V) chloride, and ruthenium(III) chloride, as oxidizing agent.

Examples of compounds having the formula HO—[Z—O]ₚ—Rₑ or HOR_{f} that may be converted to the metal salt, typically sodium salt, and used to produce 3,4-disubstituted thiophene monomers include, but are not limited to, trifluoroethanol, ethylene glycol monohexyl ether (hexyl Cellosolve), propylene glycol monobutyl ether (Dowanol PnB), diethylene glycol monoethyl ether (ethyl Carbitol), dipropylene glycol n-butyl ether (Dowanol DPnB), diethylene glycol monophenyl ether (phenyl Carbitol), ethylene glycol monobutyl ether (butyl Cellosolve), diethylene glycol monobutyl ether (butyl Carbitol), dipropylene glycol monomethyl ether (Dowanol DPM), diisobutyl carbinol, 2-ethylhexyl alcohol, methyl isobutyl carbinol, ethylene glycol monophenyl ether (Dowanol Eph), propylene glycol monopropyl ether (Dowanol PnP), propylene glycol monophenyl ether (Dowanol PPh), diethylene glycol monopropyl ether (propyl Carbitol), diethylene glycol monohexyl ether (hexyl Carbitol), 2-ethylhexyl carbitol, dipropylene glycol monopropyl ether (Dowanol DPnP), tripropylene glycol monomethyl ether (Dowanol TPM), diethylene glycol monomethyl ether (methyl Carbitol), and tripropylene glycol monobutyl ether (Dowanol TPnB).

The polythiophene having a repeating unit complying with formula (I) of the present disclosure may be further modified subsequent to its formation by polymerization.

For instance, polythiophenes having one or more repeating units derived from 3-substituted thiophene monomers may possess one or more sites where hydrogen may be replaced by a substituent, such as a sulfonic acid group (—SO₃H) by sulfonation.

As used herein, the term “sulfonated” in relation to the polythiophene polymer means that the polythiophene comprises one or more sulfonic acid groups (—SO₃H). Typically, the sulfur atom of the —SO₃H group is directly bonded to the backbone of the polythiophene polymer and not to a side group. For the purpose of the present disclosure, a side group is a monovalent radical that when theoretically or actually removed from the polymer does not shorten the length of the polymer chain. The sulfonated polythiophene polymer and/or copolymer may be made using any method known to those of ordinary skill in the art. For example, the polythiophene may be sulfonated by reacting the polythiophene with a sulfonating reagent such as, for example, fuming sulfuric acid, acetyl sulfate, pyridine SO₃, or the like. In another example, monomers may be sulfonated using a sulfonating reagent and then polymerized according to known methods and/or methods described herein. It would be understood by the ordinarily-skilled artisan that sulfonic acid groups in the presence of a basic compound, for example, alkali metal hydroxides, ammonia, and alkylamines, such as, for example, mono-, di-, and trialkylamines, such as, for example, triethylamine, may result in the formation of the corresponding salt or adduct. Thus, the term “sulfonated” in relation to the polythiophene polymer includes the meaning that the polythiophene may comprise one or more —SO₃M groups, wherein M may be an alkali metal ion, such as, for example, Na⁺, Li⁺, K⁺, Rb⁺, Cs⁺; ammonium (NH₄⁺), mono-, di-, and trialkylammonium, such as triethylammonium.

The sulfonation of conjugated polymers and sulfonated conjugated polymers, including sulfonated polythiophenes, are described in U.S. Pat. No. 8,017,241 to Seshadri et al., which is incorporated herein by reference in its entirety.

In an embodiment, the polythiophene is sulfonated.

In an embodiment, the polythiophene is sulfonated poly(3-MEET).

The polythiophene polymers used according to the present disclosure may be homopolymers or copolymers, including statistical, random, gradient, and block copolymers. For a polymer comprising a monomer A and a monomer B, block copolymers include, for example, A-B diblock copolymers, A-B-A triblock copolymers, and -(AB)ₙ-multiblock copolymers. The polythiophene may comprise repeating units derived from other types of monomers such as, for example, thienothiophenes, selenophenes, pyrroles, furans, tellurophenes, anilines, arylamines, and arylenes, such as, for example, phenylenes, phenylene vinylenes, and fluorenes.

In an embodiment, the polythiophene comprises repeating units complying with formula (I) in an amount of greater than 50% by weight, typically greater than 80% by weight, more typically greater than 90% by weight, even more typically greater than 95% by weight, based on the total weight of the repeating units.

It would be clear to a person of ordinary skill in the art that, depending on the purity of the starting monomer compound(s) used in the polymerization, the polymer formed may contain repeating units derived from impurities. As used herein, the term “homopolymer” is intended to mean a polymer comprising repeating units derived from one type of monomer, but may contain repeating units derived from impurities. In an embodiment, the polythiophene is a homopolymer wherein essentially all of the repeating units are repeating units complying with formula (I).

The polythiophene polymer typically has a number average molecular weight between about 1,000 and 1,000,000 g/mol. More typically, the conjugated polymer has a number average molecular weight between about 5,000 and 100,000 g/mol, even more typically about 10,000 to about 50,000 g/mol. Number average molecular weight may be determined according to methods known to those of ordinary skill in the art, such as, for example, by gel permeation chromatography.

The non-aqueous ink composition of the present disclosure may optionally further comprise other hole carrier compounds.

Optional hole carrier compounds include, for example, low molecular weight compounds or high molecular weight compounds. The optional hole carrier compounds may be non-polymeric or polymeric. Non-polymeric hole carrier compounds include, but are not limited to, cross-linkable and non-crosslinked small molecules. Examples of non-polymeric hole carrier compounds include, but are not limited to, N,N′-bis(3-methylphenyl)-N,N′-bis(phenyl)benzidine (CAS #65181-78-4); N,N′-bis(4-methylphenyl)-N,N′-bis(phenyl)benzidine; N,N′-bis(2-naphtalenyl)-N—N′-bis(phenylbenzidine) (CAS #139255-17-1); 1,3,5-tris(3-methyldiphenylamino)benzene (also referred to as m-MTDAB); N,N′-bis(1-naphtalenyl)-N,N′-bis(phenyl)benzidine (CAS #123847-85-8, NPB); 4,4′,4″-tris(N,N-phenyl-3-methylphenylamino)triphenylamine (also referred to as m-MTDATA, CAS #124729-98-2); 4,4′,N,N′-diphenylcarbazole (also referred to as CBP, CAS #58328-31-7); 1,3,5-tris(diphenylamino)benzene; 1,3,5-tris(2-(9-ethylcarbazyl-3)ethylene)benzene; 1,3,5-tris[(3-methylphenyl)phenylamino]benzene; 1,3-bis(N-carbazolyl)benzene; 1,4-bis(diphenylamino)benzene; 4,4′-bis(N-carbazolyl)-1,1′-biphenyl; 4,4′-bis(N-carbazolyl)-1,1′-biphenyl; 4-(dibenzylamino)benzaldehyde-N,N-diphenylhydrazone; 4-(diethylamino)benzaldehyde diphenylhydrazone; 4-(dimethylamino)benzaldehyde diphenylhydrazone; 4-(diphenylamino)benzaldehyde diphenylhydrazone; 9-ethyl-3-carbazolecarboxaldehyde diphenylhydrazone; copper(II) phthalocyanine; N,N′-bis(3-methylphenyl)-N,N′-diphenylbenzidine; N,N′-di-[(1-naphthyl)-N,N′-diphenyl]-1,1′-biphenyl)-4,4′-diamine; N,N′-diphenyl-N,N′-di-p-tolylbenzene-1,4-diamine; tetra-N-phenylbenzidine; titanyl phthalocyanine; tri-p-tolylamine; tris(4-carbazol-9-ylphenyl)amine; and tris[4-(diethylamino)phenyl]amine.

Optional polymeric hole carrier compounds include, but are not limited to, poly[(9,9-dihexylfluorenyl-2,7-diyl)-alt-co-(N,N′-bis{p-butylphenyl}-1,4-diaminophenylene)]; poly[(9,9-dioctylfluorenyl-2,7-diyl)-alt-co-(N,N′-bis{p-butylphenyl}-1,1′-biphenylene-4,4′-diamine)]; poly(9,9-dioctylfluorene-co-N-(4-butylphenyl)diphenylamine) (also referred to as TFB) and poly[N,N′-bis(4-butylphenyl)-N,N′-bis(phenyl)-benzidine](commonly referred to as poly-TPD).

Other optional hole carrier compounds are described in, for example, US Patent Publications 2010/0292399 published Nov. 18, 2010; 2010/010900 published May 6, 2010; and 2010/0108954 published May 6, 2010. Optional hole carrier compounds described herein are known in the art and are commercially available.

The polythiophene comprising a repeating unit complying with formula (I) may be doped or undoped.

In an embodiment, the polythiophene comprising a repeating unit complying with formula (I) is doped with a dopant. Dopants are known in the art. See, for example, U.S. Pat. No. 7,070,867; US Publication 2005/0123793; and US Publication 2004/0113127. The dopant can be an ionic compound. The dopant can comprise a cation and an anion. One or more dopants may be used to dope the polythiophene comprising a repeating unit complying with formula (I).

The cation of the ionic compound can be, for example, V, Cr, Mn, Fe, Co, Ni, Cu, Nb, Mo, Tc, Ru, Rh, Pd, Ag, Ta, W, Re, Os, Ir, Pt, or Au.

The cation of the ionic compound can be, for example, gold, molybdenum, rhenium, iron, and silver cation.

In some embodiments, the dopant can comprise a sulfonate or a carboxylate, including alkyl, aryl, and heteroaryl sulfonates and carboxylates. As used herein, “sulfonate” refers to a —SO₃M group, wherein M may be H⁺ or an alkali metal ion, such as, for example, Na⁺, Li⁺, K⁺, Rb⁺, Cs⁺; or ammonium (NH₄⁺). As used herein, “carboxylate” refers to a —CO₂M group, wherein M may be H⁺ or an alkali metal ion, such as, for example, Na⁺, Li⁺, K⁺, Rb⁺, Cs⁺; or ammonium (NH₄⁺). Examples of sulfonate and carboxylate dopants include, but are not limited to, benzoate compounds, heptafluorobutyrate, methanesulfonate, trifluoromethanesulfonate, p-toluenesulfonate, pentafluoropropionate, and polymeric sulfonates, perfluorosulfonate-containing ionomers, and the like.

In some embodiments, the dopant does not comprise a sulfonate or a carboxylate.

In some embodiments, dopants may comprise sulfonylimides, such as, for example, bis(trifluoromethanesulfonyl)imide; antimonates, such as, for example, hexafluoroantimonate; arsenates, such as, for example, hexafluoroarsenate; phosphorus compounds, such as, for example, hexafluorophosphate; and borates, such as, for example, tetrafluoroborate, tetraarylborates, and trifluoroborates. Examples of tetraarylborates include, but are not limited to, halogenatedtetraarylborates, such as tetrakispentafluorophenylborate (TPFB). Examples of trifluoroborates include, but are not limited to, (2-nitrophenyl)trifluoroborate, benzofurazan-5-trifluoroborate, pyrimidine-5-trifluoroborate, pyridine-3-trifluoroborate, and 2,5-dimethylthiophene-3-trifluoroborate.

As disclosed herein, the polythiophene can be doped with a dopant. A dopant can be, for example, a material that will undergo one or more electron transfer reaction(s) with, for example, a conjugated polymer, thereby yielding a doped polythiophene. The dopant can be selected to provide a suitable charge balancing counter-anion. A reaction can occur upon mixing of the polythiophene and the dopant as known in the art. For example, the dopant may undergo spontaneous electron transfer from the polymer to a cation-anion dopant, such as a metal salt, leaving behind a conjugated polymer in its oxidized form with an associated anion and free metal. See, for example, Lebedev et al., Chem. Mater., 1998, 10, 156-163. As disclosed herein, the polythiophene and the dopant can refer to components that will react to form a doped polymer. The doping reaction can be a charge transfer reaction, wherein charge carriers are generated, and the reaction can be reversible or irreversible. In some embodiments, silver ions may undergo electron transfer to or from silver metal and the doped polymer.

In the final formulation, the composition can be distinctly different from the combination of original components (i.e., polythiophene and/or dopant may or may not be present in the final composition in the same form before mixing).

Some embodiments allow for removal of reaction by-products from the doping process. For example, the metals, such as silver, can be removed by filtrations.

Materials can be purified to remove, for example, halogens and metals. Halogens include, for example, chloride, bromide and iodide. Metals include, for example, the cation of the dopant, including the reduced form of the cation of the dopant, or metals left from catalyst or initiator residues. Metals include, for example, silver, nickel, and magnesium. The amounts can be less than, for example, 100 ppm, or less than 10 ppm, or less than 1 ppm.

Metal content, including silver content, can be measured by ICP-MS, particularly for concentrations greater than 50 ppm.

In an embodiment, when the polythiophene is doped with a dopant, the polythiophene and the dopant are mixed to form a doped polymer composition. Mixing may be achieved using any method known to those of ordinary skill in the art. For example, a solution comprising the polythiophene may be mixed with a separate solution comprising the dopant. The solvent or solvents used to dissolve the polythiophene and the dopant may be one or more solvents described herein. A reaction can occur upon mixing of the polythiophene and the dopant as known in the art. The resulting doped polythiophene composition comprises between about 40% and 75% by weight of the polymer and between about 25% and 55% by weight of the dopant, based on the composition. In another embodiment, the doped polythiophene composition comprises between about 50% and 65% for the polythiophene and between about 35% and 50% of the dopant, based on the composition. Typically, the amount by weight of the polythiophene is greater than the amount by weight of the dopant. Typically, the dopant can be a silver salt, such as silver tetrakis(pentafluorophenyl)borate in an amount of about 0.25 to 0.5 m/ru, wherein m is the molar amount of silver salt and ru is the molar amount of polymer repeat unit.

The doped polythiophene is isolated according to methods known to those of ordinary skill in the art, such as, for example, by rotary evaporation of the solvent, to obtain a dry or substantially dry material, such as a powder. The amount of residual solvent can be, for example, 10 wt. % or less, or 5 wt. % or less, or 1 wt. % or less, based on the dry or substantially dry material. The dry or substantially dry powder can be redispersed or redissolved in one or more new solvents.

The non-aqueous ink compositions of the present disclosure comprise one or more metalloid nanoparticles.

As used herein, the term “metalloid” refers to an element having chemical and/or physical properties intermediate of, or that are a mixture of, those of metals and nonmetals. Herein, the term “metalloid” refers to boron (B), silicon (Si), germanium (Ge), arsenic (As), antimony (Sb), and tellurium (Te).

As used herein, the term “nanoparticle” refers to a nanoscale particle, the number average diameter of which is typically less than or equal to 500 nm. The number average diameter may be determined using techniques and instrumentation known to those of ordinary skill in the art. For instance, transmission electron microscopy (TEM) may be used.

TEM may be used to characterize size and size distribution, among other properties, of the metalloid nanoparticles. Generally, TEM works by passing an electron beam through a thin sample to form an image of the area covered by the electron beam with magnification high enough to observe the lattice structure of a crystal. The measurement sample is prepared by evaporating a dispersion having a suitable concentration of nanoparticles on a specially-made mesh grid. The crystal quality of the nanoparticles can be measured by the electron diffraction pattern and the size and shape of the nanoparticles can be observed in the resulting micrograph image.

Typically, the number of nanoparticles and projected two-dimensional area of every nanoparticle in the field-of-view of the image, or fields-of-view of multiple images of the same sample at different locations, are determined using image processing software, such as ImageJ (available from US National linstitutes of Health). The projected two-dimensional area, A, of each nanoparticle measured is used to calculate its circular equivalent diameter, or area-equivalent diameter, X_{A}, which is defined as the diameter of a circle with the same area as the nanoparticle. The circular equivalent diameter is simply given by the equation

$${x}_{A} = \sqrt{\frac{4 A}{π}}$$

The arithmetic average of the circular equivalent diameters of all of the nanoparticles in the observed image is then calculated to arrive at the number average particle diameter, as used herein. A variety of TEM microscopes available, for instance, Jeol JEM-2100F Field Emission TEM and Jeol JEM 2100 LaB6 TEM (available from JEOL USA). It is understood that all TE microscopes function on similar principles and when operated according to standard procedures, the results are interchangeable.

The number average particle diameter of the metalloid nanoparticles described herein is less than or equal to 500 nm; less than or equal to 250 nm; less than or equal to 100 nm; or less than or equal to 50 nm; or less than or equal to 25 nm. Typically, the metalloid nanoparticles have number average particle diameter from about 1 nm to about 100 nm, more typically from about 2 nm to about 30 nm.

The shape or geometry of metalloid nanoparticles of the present disclosure can be characterized by number average aspect ratio. As used herein, the terminology “aspect ratio” means the ratio of the Feret's minimum length to the Feret's maximum length, or

$$\frac{{x}_{F m i n}}{{x}_{F ma x}} .$$

As used herein, the maximum Feret's diameter, X_{Fmax}, is defined as the furthest distance between any two parallel tangents on the two-dimensional projection of a particle in a TEM micrograph. Likewise, the minimum Feret's diameter, X_{Fmin}, is defined as the shortest distance between any two parallel tangents on the two-dimensional projection of a particle in a TEM micrograph. The aspect ratio of each particle in the field-of-view of a micrograph is calculated and the arithmetic average of the aspect ratios of all of the particles in the image is calculated to arrive at the number average aspect ratio. Generally, the number average aspect ratio of the metalloid nanoparticles described herein is from about 0.9 to about 1.1, typically about 1.

The metalloid nanoparticles suitable for use according to the present disclosure may comprise boron (B), silicon (Si), germanium (Ge), arsenic (As), antimony (Sb), tellurium (Te), tin (Sn) and/or oxides thereof. Some non-limiting, specific examples of suitable metalloid nanoparticles include, but are not limited to, nanoparticles comprising B₂O₃, B₂O, SiO₂, SiO, GeO₂, GeO, As₂O₄, As₂O₃, As₂O₅, Sb₂O₃, TeO₂, and mixtures thereof.

In an embodiment, the non-aqueous ink composition of the present disclosure comprises one or more metalloid nanoparticles comprising B₂O₃, B₂O, SiO₂, SiO, GeO₂, GeO, As₂O₄, As₂O₃, As₂O₅, SnO₂, SnO, Sb₂O₃, TeO₂, or mixtures thereof.

In an embodiment, the non-aqueous ink composition of the present disclosure comprises one or more metalloid nanoparticles comprising SiO₂.

The metalloid nanoparticles may comprise one or more organic capping groups.

Such organic capping groups may be reactive or non-reactive. Reactive organic capping groups are organic capping groups capable of cross-linking, for example, in the presence of UV radiation or radical initiators.

In an embodiment, the metalloid nanoparticles comprise one or more organic capping groups.

Examples of suitable metalloid nanoparticles include SiO₂ nanoparticles available as dispersions in various solvents, such as, for example, methyl ethyl ketone, methyl isobutyl ketone, N,N-dimethylacetamide, ethylene glycol, isopropanol, methanol, ethylene glycol monopropyl ether, and propylene glycol monomethyl ether acetate, marketed as ORGANOSILICASOL™ by Nissan Chemical.

The amount of the metalloid nanoparticles used in the non-aqueous ink composition described herein can be controlled and measured as a weight percentage relative to the combined weight of the metalloid nanoparticles and the doped or undoped polythiophene. In an embodiment, the amount of the metalloid nanoparticles is from 1 wt. % to 98 wt. %, typically from about 2 wt. to about 95 wt. %, more typically from about 5 wt. % to about 90 wt. %, still more typically about 10 wt. % to about 90 wt. %, relative to the combined weight of the metalloid nanoparticles and the doped or undoped polythiophene. In an embodiment, the amount of the metalloid nanoparticles is from about 20 wt. % to about 98 wt. %, typically from about 25 wt. to about 95 wt. %, relative to the combined weight of the metalloid nanoparticles and the doped or undoped polythiophene.

The non-aqueous ink composition of the present disclosure may optionally further comprise one or more matrix compounds known to be useful in hole injection layers (HILs) or hole transport layers (HTLs).

The optional matrix compound can be a lower or higher molecular weight compound, and is different from the polythiophene described herein. The matrix compound can be, for example, a synthetic polymer that is different from the polythiophene. See, for example, US Patent Publication No. 2006/0175582 published Aug. 10, 2006. The synthetic polymer can comprise, for example, a carbon backbone. In some embodiments, the synthetic polymer has at least one polymer side group comprising an oxygen atom or a nitrogen atom. The synthetic polymer may be a Lewis base. Typically, the synthetic polymer comprises a carbon backbone and has a glass transition temperature of greater than 25° C. The synthetic polymer may also be a semi-crystalline or crystalline polymer that has a glass transition temperature equal to or lower than 25° C. and/or a melting point greater than 25° C. The synthetic polymer may comprise one or more acidic groups, for example, sulfonic acid groups.

In an embodiment, the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

In an embodiment, the polymeric acid comprises a repeating unit complying with formula (II) and a repeating unit complying with formula (III)

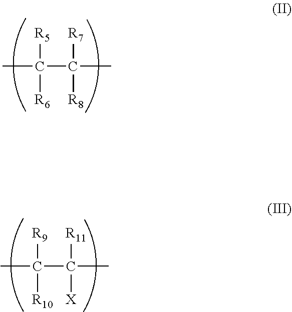

wherein each occurrence of R₅, R₆, R₇, R₈, R₉, R₁₀, and R₁₁ is, independently, H, halogen, fluoroalkyl, or perfluoroalkyl; and X is —[OC(RₕRᵢ)—C(RⱼRₖ)]_{q}—O—[CRₗRₘ]_{z}—SO₃H, wherein each occurrence of Rₕ, Rᵢ, Rⱼ, Rₖ, Rₗ and Rₘ is, independently, H, halogen, fluoroalkyl, or perfluoroalkyl; q is 0 to 10; and z is 1-5.

In an embodiment, each occurrence of R₅, R₆, R₇, and R₈ is, independently, Cl or F.

In an embodiment, each occurrence of R₅, R₇, and R₈ is F, and R₆ is Cl. In an embodiment, each occurrence of R₅, R₆, R₇, and R₈ is F.

In an embodiment, each occurrence of R₉, R₁₀, and R₁₁ is F.

In an embodiment, each occurrence of Rₕ, Rᵢ, Rⱼ, Rₖ, Rₗ and Rₘ is, independently, F, (C₁-C₈)fluoroalkyl, or (C₁-C₈)perfluoroalkyl.

In an embodiment, each occurrence of Rₗ and Rₘ is F; q is 0; and z is 2.

In an embodiment, each occurrence of R₅, R₇, and R₅ is F, and R₆ is Cl; and each occurrence of Rₗ and Rₘ is F; q is 0; and z is 2.

In an embodiment, each occurrence of R₅, R₆, R₇, and R₅ is F; and each occurrence of Rₗ and Rₘ is F; q is 0; and z is 2.

The ratio of the number of repeating units complying with formula (II) (“n”) to the number of the repeating units complying with formula (III) (“m”) is not particularly limited. The n:m ratio is typically from 9:1 to 1:9, more typically 8:2 to 2:8. In an embodiment, the n:m ratio is 9:1. In an embodiment, the n:m ratio is 8:2.

The polymeric acid suitable for use according to the present disclosure may be synthesized using methods known to those of ordinary skill in the art or obtained from commercially-available sources. For instance, the polymers comprising a repeating unit complying with formula (II) and a repeating unit complying with formula (III) may be made by co-polymerizing monomers represented by formula (IIa) with monomers represented by formula (IIa)

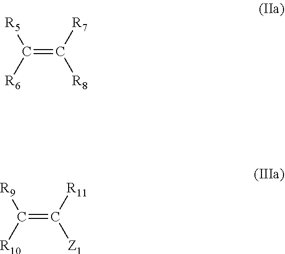

wherein Z₁ is —[OC(RₕRᵢ)—C(RⱼRₖ)]_{q}—O—[CRₗRₘ]_{z}—SO₂F, wherein Rₕ, Rᵢ, Rⱼ, Rₖ, Rₗ and Rₘ, q, and z are as defined herein, according to known polymerization methods, followed by conversion to sulfonic acid groups by hydrolysis of the sulfonyl fluoride groups.

For example, tetrafluoroethylene (TFE) or chlorotrifluoroethylene (CTFE) may be copolymerized with one or more fluorinated monomers comprising a precursor group for sulfonic acid, such as, for example, F₂C═CF—O—CF₂—CF₂—SO₂F; F₂C═CF—[O—CF₂—CR₁₂F—O]_{q}—CF₂—CF₂—SO₂F, wherein R₁₂ is F or CF₃ and q is 1 to 10; F₂C═CF—O—CF₂—CF₂—CF₂—SO₂F; and F₂C═CF—OCF₂—CF₂—CF₂—CF₂—SO₂F.

The equivalent weight of the polymeric acid is defined as the mass, in grams, of the polymeric acid per mole of acidic groups present in the polymeric acid. The equivalent weight of the polymeric acid is from about 400 to about 15,000 g polymer/mol acid, typically from about 500 to about 10,000 g polymer/mol acid, more typically from about 500 to 8,000 g polymer/mol acid, even more typically from about 500 to 2,000 g polymer/mol acid, still more typically from about 600 to about 1,700 g polymer/mol acid.

Such polymeric acids are, for instance, those marketed by E. I. DuPont under the trade name NAFION®, those marketed by Solvay Specialty Polymers under the trade name AQUIVION®, or those marketed by Asahi Glass Co. under the trade name FLEMION®.

In an embodiment, the synthetic polymer is a polyether sulfone comprising one or more repeating units comprising at least one sulfonic acid (—SO₃H) moiety.

In an embodiment, the polyether sulfone comprises a repeating unit complying with formula (IV)

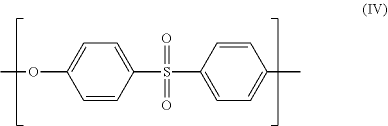

and a repeating unit selected from the group consisting of a repeating unit complying with formula (V) and a repeating unit complying with formula (VI)

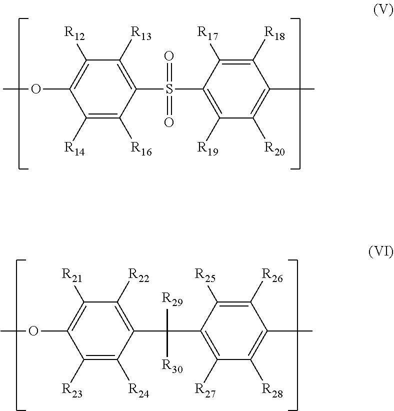

wherein R₁₂-R₂₀ are each, independently, H, halogen, alkyl, or SO₃H, provided that at least one of R₁₂-R₂₀ is SO₃H; and wherein R₂₁-R₂₈ are each, independently, H, halogen, alkyl, or SO₃H, provided that at least one of R₂₁-R₂₈ is SO₃H, and R₂₉ and R₃₀ are each H or alkyl.

In an embodiment, R₂₉ and R₃₀ are each alkyl. In an embodiment, R₂₉ and R₃₀ are each methyl.

In an embodiment, R₁₂-R₁₇, R₁₉, and R₂₀, are each H and R₁₈ is SO₃H.

In an embodiment, R₂₁-R₂₅, R₂₇, and R₂₈, are each H and R₂₆ is SO₃H.

In an embodiment, the polyether sulfone is represented by formula (VII)

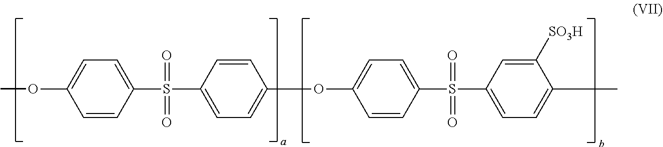

wherein a is from 0.7 to 0.9 and b is from 0.1 to 0.3.

The polyether sulfone may further comprise other repeating units, which may or may not be sulfonated.

For example, the polyether sulfone may comprise a repeating unit of formula (VIII)

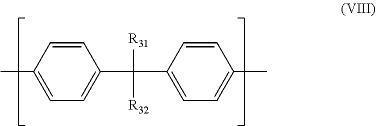

wherein R₃₁ and R₃₂ are each, independently, H or alkyl.

Any two or more repeating units described herein may together form a repeating unit and the polyether sulfone may comprise such a repeating unit. For example, the repeating unit complying with formula (IV) may be combined with a repeating unit complying with formula (VI) to give a repeating unit complying with formula (IX)

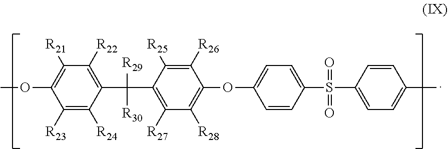

Analogously, for example, the repeating unit complying with formula (IV) may be combined with a repeating unit complying with formula (VIII) to give a repeating unit complying with formula (X)

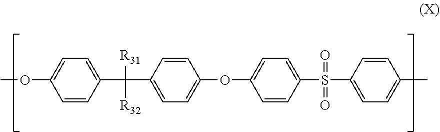

In an embodiment, the polyether sulfone is represented by formula (XI)

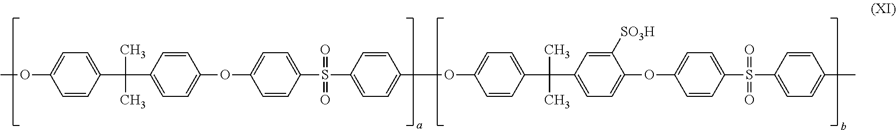

wherein a is from 0.7 to 0.9 and b is from 0.1 to 0.3.

Polyether sulfones comprising one or more repeating units comprising at least one sulfonic acid (—SO₃H) moiety are commercially-available, for example, sulfonated polyether sulfones marketed as S-PES by Konishi Chemical Ind.Co., Ltd.

The optional matrix compound can be a planarizing agent. A matrix compound or a planarizing agent may be comprised of, for example, a polymer or oligomer such as an organic polymer, such as poly(styrene) or poly(styrene) derivatives; poly(vinyl acetate) or derivatives thereof; poly(ethylene glycol) or derivatives thereof; poly(ethylene-co-vinyl acetate); poly(pyrrolidone) or derivatives thereof (e.g., poly(1-vinylpyrrolidone-co-vinyl acetate)); poly(vinyl pyridine) or derivatives thereof; poly(methyl methacrylate) or derivatives thereof; poly(butyl acrylate); poly(aryl ether ketones); poly(aryl sulfones); poly(esters) or derivatives thereof; or combinations thereof.

In an embodiment, the matrix compound is poly(styrene) or poly(styrene) derivative.

In an embodiment, the matrix compound is poly(4-hydroxystyrene).

The optional matrix compound or planarizing agent may be comprised of, for example, at least one semiconducting matrix component. The semiconducting matrix component is different from the polythiophene described herein. The semiconducting matrix component can be a semiconducting small molecule or a semiconducting polymer that is typically comprised of repeat units comprising hole carrying units in the main-chain and/or in a side-chain. The semiconducting matrix component may be in the neutral form or may be doped, and is typically soluble and/or dispersible in organic solvents, such as toluene, chloroform, acetonitrile, cyclohexanone, anisole, chlorobenzene, o-dichlorobenzene, ethyl benzoate and mixtures thereof.

The amount of the optional matrix compound can be controlled and measured as a weight percentage relative to the amount of the doped or undoped polythiophene. In an embodiment, the amount of the optional matrix compound is from 0 to 99.5 wt. %, typically from about 10 wt. to about 98 wt. %, more typically from about 20 wt. % to about 95 wt. %, still more typically about 25 wt. % to about 45 wt. %, relative to the amount of the doped or undoped polythiophene. In the embodiment with 0 wt. %, the ink composition is free of matrix compound.

The ink compositions of the present disclosure are non-aqueous. As used herein, “non-aqueous” means that the total amount of water present in the ink compositions of the present disclosure is from 0 to 5% wt., with respect to the total amount of the liquid carrier. Typically, the total amount of water in the ink composition is from 0 to 2% wt, more typically from 0 to 1% wt, even more typically from 0 to 0.5% wt, with respect to the total amount of the liquid carrier. In an embodiment, the ink composition of the present disclosure is free of any water.

The non-aqueous ink compositions of the present disclosure may optionally comprise one or more amine compounds. Suitable amine compounds for use in the non-aqueous ink compositions of the present disclosure include, but are not limited to, ethanolamines and alkylamines.

Examples of suitable ethanolamines include dimethylethanol amine [(CH₃)₂NCH₂CH₂OH], triethanol amine [N(CH₂CH₂OH)₃], and N-tert-Butyldiethanol amine [t-C₄H₉N(CH₂CH₂OH)₂].

Alkylamines include primary, secondary, and tertiary alkylamines. Examples of primary alkylamines include, for example, ethylamine [C₂H₅NH₂], n-butylamine [C₄H₉NH₂], t-butylamine [C₄H₉NH₂], n-hexylamine[C₆H₁₃NH₂], n-decylamine[C₁₀H₂₁NH₂], and ethylenediamine [H₂NCH₂CH₂NH₂]. Secondary alkylamines include, for example, diethylamine [(C₂H₅)₂NH], di(n-propylamine) [(n-C₃H₉)₂NH], di(iso-propylamine) [(i-C₃H₉)₂NH], and dimethyl ethylenediamine [CH₃NHCH₂CH₂NHCH₃]. Tertiary alkylamines include, for example, trimethylamine [(CH₃)₃N], triethylamine [(C₂H₅)₃N], tri(n-butyl)amine [(C₄H₉)₃N], and tetramethyl ethylenediamine [(CH₃)₂NCH₂CH₂N(CH₃)₂].

In an embodiment, the amine compound is a tertiary alkylamine. In an embodiment, the amine compound is triethylamine.

The amount of the amine compound can be controlled and measured as a weight percentage relative to the total amount of the ink composition. In an embodiment, the amount of the amine compound is at least 0.01 wt. %, at least 0.10 wt. %, at least 1.00 wt. %, at least 1.50 wt. %, or at least 2.00 wt. %, with respect to the total amount of the ink composition. In an embodiment, the amount of the amine compound is from about 0.01 to about 2.00 wt. %, typically from about 0.05% wt. to about 1.50 wt. %, more typically from about 0.1 wt. % to about 1.0 wt. %, with respect to the total amount of the ink composition.

The liquid carrier used in the ink composition according to the present disclosure comprises one or more organic solvents. In an embodiment, the ink composition consists essentially of or consists of one or more organic solvents. The liquid carrier may be an organic solvent or solvent blend comprising two or more organic solvents adapted for use and processing with other layers in a device such as the anode or light emitting layer.

Organic solvents suitable for use in the liquid carrier include, but are not limited to, aliphatic and aromatic ketones, organosulfur solvents, such as dimethyl sulfoxide (DMSO) and 2,3,4,5-tetrahydrothiophene-1,1-dioxide (tetramethylene sulfone; Sulfolane), tetrahydrofuran (THF), tetrahydropyran (THP), tetramethyl urea (TMU), N,N′-dimethylpropyleneurea, alkylated benzenes, such as xylene and isomers thereof, halogenated benzenes, N-methylpyrrolidinone (NMP), dimethylformamide (DMF), dimethylacetamide (DMAc), dichloromethane, acetonitrile, dioxanes, ethyl acetate, ethyl benzoate, methyl benzoate, dimethyl carbonate, ethylene carbonate, propylene carbonate, 3-methoxypropionitrile, 3-ethoxypropionitrile, or combinations thereof.

Aliphatic and aromatic ketones include, but are not limited to, acetone, acetonyl acetone, methyl ethyl ketone (MEK), methyl isobutyl ketone, methyl isobutenyl ketone, 2-hexanone, 2-pentanone, acetophenone, ethyl phenyl ketone, cyclohexanone, and cyclopentanone. In some embodiments, ketones with protons on the carbon located alpha to the ketone are avoided, such as cyclohexanone, methyl ethyl ketone, and acetone.

Other organic solvents might also be considered that solubilize, completely or partially, the polythiophene polymer or that swell the polythiophene polymer. Such other solvents may be included in the liquid carrier in varying quantities to modify ink properties such as wetting, viscosity, morphology control. The liquid carrier may further comprise one or more organic solvents that act as non-solvents for the polythiophene polymer.

Other organic solvents suitable for use according to the present disclosure include ethers such as anisole, ethoxybenzene, dimethoxy benzenes and glycol ethers, such as, ethylene glycol diethers, such as 1,2-dimethoxyethane, 1,2-diethoxyethane, and 1,2-dibutoxyethane; diethylene glycol diethers such as diethylene glycol dimethyl ether, and diethylene glycol diethyl ether; propylene glycol diethers such as propylene glycol dimethyl ether, propylene glycol diethyl ether, and propylene glycol dibutyl ether; dipropylene glycol diethers, such as dipropylene glycol dimethyl ether, dipropylene glycol diethyl ether, and dipropylene glycol dibutyl ether; as well as higher analogues (i.e., tri- and tetra-analogues) of the ethylene glycol and propylene glycol ethers mentioned herein.

Still other solvents can be considered, such as ethylene glycol monoether acetates and propylene glycol monoether acetates, wherein the ether can be selected, for example, from methyl, ethyl, n-propyl, iso-propyl, n-butyl, sec-butyl, tert-butyl, and cyclohexyl. Also, higher glycol ether analogues of above list such as di-, tri- and tetra-. Examples include, but are not limited to, propylene glycol methyl ether acetate, 2-ethoxyethyl acetate, 2-butoxyethyl acetate.

Alcohols may also be considered for use in the liquid carrier, such as, for example, methanol, ethanol, trifluoroethanol, n-propanol, isopropanol, n-butanol, t-butanol, and and alkylene glycol monoethers. Examples of suitable alkylene glycol monoethers include, but are not limited to, ethylene glycol monohexyl ether (hexyl Cellosolve), propylene glycol monobutyl ether (Dowanol PnB), diethylene glycol monoethyl ether (ethyl Carbitol), dipropylene glycol n-butyl ether (Dowanol DPnB), diethylene glycol monophenyl ether (phenyl Carbitol), ethylene glycol monobutyl ether (butyl Cellosolve), diethylene glycol monobutyl ether (butyl Carbitol), dipropylene glycol monomethyl ether (Dowanol DPM), diisobutyl carbinol, 2-ethylhexyl alcohol, methyl isobutyl carbinol, ethylene glycol monophenyl ether (Dowanol Eph), propylene glycol monopropyl ether (Dowanol PnP), propylene glycol monophenyl ether (Dowanol PPh), diethylene glycol monopropyl ether (propyl Carbitol), diethylene glycol monohexyl ether (hexyl Carbitol), 2-ethylhexyl carbitol, dipropylene glycol monopropyl ether (Dowanol DPnP), tripropylene glycol monomethyl ether (Dowanol TPM), diethylene glycol monomethyl ether (methyl Carbitol), and tripropylene glycol monobutyl ether (Dowanol TPnB).

As disclosed herein, the organic solvents disclosed herein can be used in varying proportions in the liquid carrier, for example, to improve the ink characteristics such as substrate wettability, ease of solvent removal, viscosity, surface tension, and jettability.

In some embodiments, the use of aprotic non-polar solvents can provide the additional benefit of increased life-times of devices with emitter technologies which are sensitive to protons, such as, for example, PHOLEDs.

In an embodiment, the liquid carrier comprises dimethyl sulfoxide, ethylene glycol, tetramethyl urea, or a mixture thereof.

The amount of liquid carrier in the ink composition according to the present disclosure is from about 50 wt. % to about 99 wt. %, typically from about 75 wt. % to about 98 wt. %, still more typically from about 90 wt. % to about 95 wt. %, with respect to the total amount of ink composition.

The total solids content (% TS) in the ink composition according to the present disclosure is from about 0.1 wt. % to about 50 wt. %, typically from about 0.3 wt. % to about 40 wt. %, more typically from about 0.5 wt. % to about 15 wt. %, still more typically from about 1 wt. % to about 5 wt. %, with respect to the total amount of ink composition.

The non-aqueous ink compositions described herein may be prepared according to any suitable method known to the ordinarily-skilled artisan. For example, in one method, an initial aqueous mixture is prepared by mixing an aqueous dispersion of the polythiophene described herein with an aqueous dispersion of polymeric acid, if desired, another matrix compound, if desired, and additional solvent. The solvents, including water, in the mixture are then removed, typically by evaporation. The resulting dry product is then dissolved or dispersed in one or more organic solvents, such as dimethyl sulfoxide, and filtered under pressure to yield a non-aqueous mixture. An amine compound may optionally be added to such non-aqueous mixture. The non-aqueous mixture is then mixed with a non-aqueous dispersion of the metalloid nanoparticles to yield the final non-aqueous ink composition.

In another method, the non-aqueous ink compositions described herein may be prepared from stock solutions. For example, a stock solution of the polythiophene described herein can be prepared by isolating the polythiophene in dry form from an aqueous dispersion, typically by evaporation. The dried polythiophene is then combined with one or more organic solvents and, optionally, an amine compound. If desired, a stock solution of the polymeric acid described herein can be prepared by isolating the polymeric acid in dry form from an aqueous dispersion, typically by evaporation. The dried polymeric acid is then combined with one or more organic solvents. Stock solutions of other optional matrix materials can be made analogously. Stock solutions of the metalloid nanoparticles can be made, for example, by diluting commercially-available dispersions with one or more organic solvents, which may be the same or different from the solvent or solvents contained in the commercial dispersion. Desired amounts of each stock solution are then combined to form the non-aqueous ink compositions of the present disclosure.

Still in another method, the non-aqueous ink compositions described herein may be prepared by isolating the individual components in dry form as described herein, but instead of preparing stock solutions, the components in dry form are combined and then dissolved in one or more organic solvents to provide the NQ ink composition.

The ink composition according to the present disclosure can be cast and annealed as a film on a substrate.

Thus, the present disclosure also relates to a process for forming a hole-carrying film, the process comprising:
1) coating a substrate with a non-aqueous ink composition disclosed herein; and
2) annealing the coating on the substrate, thereby forming the hole-carrying film.

The coating of the ink composition on a substrate can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

The substrate can be flexible or rigid, organic or inorganic. Suitable substrate compounds include, for example, glass, including, for example, display glass, ceramic, metal, and plastic films.

As used herein, the term “annealing” refers to any general process for forming a hardened layer, typically a film, on a substrate coated with the non-aqueous ink composition of the present disclosure. General annealing processes are known to those of ordinary skill in the art. Typically, the solvent is removed from the substrate coated with the non-aqueous ink composition. The removal of solvent may be achieved, for example, by subjecting the coated substrate to pressure less than atmospheric pressure, and/or by heating the coating layered on the substrate to a certain temperature (annealing temperature), maintaining the temperature for a certain period of time (annealing time), and then allowing the resulting layer, typically a film, to slowly cool to room temperature.

The step of annealing can be carried out by heating the substrate coated with the ink composition using any method known to those of ordinary skill in the art, for example, by heating in an oven or on a hot plate. Annealing can be carried out under an inert environment, for example, nitrogen atmosphere or noble gas atmosphere, such as, for example, argon gas. Annealing may be carried out in air atmosphere.

In an embodiment, the annealing temperature is from about 25° C. to about 350° C., typically from about 150° C. to about 325° C., more typically from about 200° C. to about 300° C., still more typically from about 230° C. to about 300° C.

The annealing time is the time for which the annealing temperature is maintained. The annealing time is from about 3 to about 40 minutes, typically from about 15 to about 30 minutes.

In an embodiment, the annealing temperature is from about 25° C. to about 350° C., typically from about 150° C. to about 325° C., more typically from about 200° C. to about 300° C., still more typically from about 250° C. to about 300° C., and the annealing time is from about 3 to about 40 minutes, typically for about 15 to about 30 minutes.

The present disclosure relates to the hole-carrying film formed by the process described herein.

Transmission of visible light is important, and good transmission (low absorption) at higher film thicknesses is particularly important. For example, the film made according to the process of the present disclosure can exhibit a transmittance (typically, with a substrate) of at least about 85%, typically at least about 90%, of light having a wavelength of about 380-800 nm. In an embodiment, the transmittance is at least about 90%.

In one embodiment, the film made according to the process of the present disclosure has a thickness of from about 5 nm to about 500 nm, typically from about 5 nm to about 150 nm, more typically from about 50 nm to 120 nm.

In an embodiment, the film made according to the process of the present disclosure exhibits a transmittance of at least about 90% and has a thickness of from about 5 nm to about 500 nm, typically from about 5 nm to about 150 nm, more typically from about 50 nm to 120 nm. In an embodiment, the film made according to the process of the present disclosure exhibits a transmittance (% T) of at least about 90% and has a thickness of from about 50 nm to 120 nm.

The films made according to the processes of the present disclosure may be made on a substrate optionally containing an electrode or additional layers used to improve electronic properties of a final device. The resulting films may be intractable to one or more organic solvents, which can be the solvent or solvents used as liquid carrier in the ink for subsequently coated or deposited layers during fabrication of a device. The films may be intractable to, for example, toluene, which can be the solvent in the ink for subsequently coated or deposited layers during fabrication of a device.

The present disclosure also relates to a device comprising a film prepared according to the processes described herein. The devices described herein can be made by methods known in the art including, for example, solution processing. Inks can be applied and solvents removed by standard methods. The film prepared according to the processes described herein may be an HIL and/or HTL layer in the device.

Methods are known in the art and can be used to fabricate organic electronic devices including, for example, OLED and OPV devices. Methods known in the art can be used to measure brightness, efficiency, and lifetimes. Organic light emitting diodes (OLED) are described, for example, in U.S. Pat. Nos. 4,356,429 and 4,539,507 (Kodak). Conducting polymers which emit light are described, for example, in U.S.

U.S. Pat. Nos. 5,247,190 and 5,401,827 (Cambridge Display Technologies). Device architecture, physical principles, solution processing, multilayering, blends, and compounds synthesis and formulation are described in Kraft et al., “Electroluminescent Conjugated Polymers-Seeing Polymers in a New Light,” Angew. Chem. Int. Ed., 1998, 37, 402-428, which is hereby incorporated by reference in its entirety.

Light emitters known in the art and commercially available can be used including various conducting polymers as well as organic molecules, such as compounds available from Sumation, Merck Yellow, Merck Blue, American Dye Sources (ADS), Kodak (e.g., A1Q3 and the like), and even Aldrich, such as BEHP-PPV. Examples of such organic electroluminescent compounds include:

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(p-phenylene vinylene) and its derivatives substituted at various positions on the phenylene moiety and also substituted at various positions on the vinylene moiety;

(iv) poly(arylene vinylene), where the arylene may be such moieties as naphthalene, anthracene, furylene, thienylene, oxadiazole, and the like;

(v) derivatives of poly(arylene vinylene), where the arylene may be as in (iv) above, and additionally have substituents at various positions on the arylene;

(vi) derivatives of poly(arylene vinylene), where the arylene may be as in (iv) above, and additionally have substituents at various positions on the vinylene;

(vii) derivatives of poly(arylene vinylene), where the arylene may be as in (iv) above, and additionally have substituents at various positions on the arylene and substituents at various positions on the vinylene;

(viii) co-polymers of arylene vinylene oligomers, such as those in (iv), (v), (vi), and (vii) with non-conjugated oligomers; and

(ix) poly(p-phenylene) and its derivatives substituted at various positions on the phenylene moiety, including ladder polymer derivatives such as poly(9,9-dialkyl fluorene) and the like;

(x) poly(arylenes) where the arylene may be such moieties as naphthalene, anthracene, furylene, thienylene, oxadiazole, and the like; and their derivatives substituted at various positions on the arylene moiety;

(xi) co-polymers of oligoarylenes, such as those in (x) with non-conjugated oligomers;

(xii) polyquinoline and its derivatives;

(xiii) co-polymers of polyquinoline with p-phenylene substituted on the phenylene with, for example, alkyl or alkoxy groups to provide solubility; and

(xiv) rigid rod polymers, such as poly(p-phenylene-2,6-benzobisthiazole), poly(p-phenylene-2,6-benzobisoxazole), poly(p-phenylene-2,6-benzimidazole), and their derivatives;

(xv) polyfluorene polymers and co-polymers with polyfluorene units.

Preferred organic emissive polymers include SUMATION Light Emitting Polymers (“LEPs”) that emit green, red, blue, or white light or their families, copolymers, derivatives, or mixtures thereof; the SUMATION LEPs are available from Sumation KK. Other polymers include polyspirofluorene-like polymers available from Covion Organic Semiconductors GmbH, Frankfurt, Germany (now owned by Merck®).

Alternatively, rather than polymers, small organic molecules that emit by fluorescence or by phosphorescence can serve as the organic electroluminescent layer. Examples of small-molecule organic electroluminescent compounds include: (i) tris(8-hydroxyquinolinato) aluminum (Alq); (ii) 1,3-bis(N,N-dimethylaminophenyl)-1,3,4-oxidazole (OXD-8); (iii) -oxo-bis(2-methyl-8-quinolinato)aluminum; (iv) bis(2-methyl-8-hydroxyquinolinato) aluminum; (v) bis(hydroxybenzoquinolinato) beryllium (BeQ₂); (vi) bis(diphenylvinyl)biphenylene (DPVBI); and (vii) arylamine-substituted distyrylarylene (DSA amine).

Such polymer and small-molecule compounds are well known in the art and are described in, for example, U.S. Pat. No. 5,047,687.

The devices can be fabricated in many cases using multilayered structures which can be prepared by, for example, solution or vacuum processing, as well as printing and patterning processes. In particular, use of the embodiments described herein for hole injection layers (HILs), wherein the composition is formulated for use as a hole injection layer, can be carried out effectively.

Examples of HIL in devices include:

1) Hole injection in OLEDs including PLEDs and SMOLEDs; for example, for HIL in PLED, all classes of conjugated polymeric emitters where the conjugation involves carbon or silicon atoms can be used. For HIL in SMOLED, the following are examples: SMOLED containing fluorescent emitters; SMOLED containing phosphorescent emitters; SMOLEDs comprising one or more organic layers in addition to the HIL layer; and SMOLEDs where the small molecule layer is processed from solution or aerosol spray or any other processing methodology. In addition, other examples include HIL in dendrimer or oligomeric organic semiconductor based OLEDs; HIL in ambipolar light emitting FET's where the HIL is used to modify charge injection or as an electrode;

2) Hole extraction layer in OPV;

3) Channel material in transistors;

4) Channel material in circuits comprising a combination of transistors, such as logic gates;

5) Electrode material in transistors;

6) Gate layer in a capacitor;

7) Chemical sensor where modification of doping level is achieved due to association of the species to be sensed with the conductive polymer;

8) Electrode or electrolyte material in batteries.

A variety of photoactive layers can be used in OPV devices. Photovoltaic devices can be prepared with photoactive layers comprising fullerene derivatives mixed with, for example, conducting polymers as described in, for example, U.S. Pat. Nos. 5,454,880; 6,812,399; and 6,933,436. Photoactive layers may comprise blends of conducting polymers, blends of conducting polymers and semiconducting nanoparticles, and bilayers of small molecules such as phthalocyanines, fullerenes, and porphyrins.

Common electrode compounds and substrates, as well as encapsulating compounds can be used.

In one embodiment, the cathode comprises Au, Ca, Al, Ag, or combinations thereof.

In one embodiment, the anode comprises indium tin oxide. In one embodiment, the light emission layer comprises at least one organic compound.

Interfacial modification layers, such as, for example, interlayers, and optical spacer layers may be used.

Electron transport layers can be used.

The present disclosure also relates to a method of making a device described herein.

In an embodiment, the method of making a device comprises: providing a substrate; layering a transparent conductor, such as, for example, indium tin oxide, on the substrate; providing the ink composition described herein; layering the ink composition on the transparent conductor to form a hole injection layer or hole transport layer; layering an active layer on the hole injection layer or hole transport layer (HTL); and layering a cathode on the active layer.

As described herein, the substrate can be flexible or rigid, organic or inorganic. Suitable substrate compounds include, for example, glass, ceramic, metal, and plastic films.

In another embodiment, a method of making a device comprises applying the ink composition as described herein as part of an HIL or HTL layer in an OLED, a photovoltaic device, an ESD, a SMOLED, a PLED, a sensor, a supercapacitor, a cation transducer, a drug release device, an electrochromic device, a transistor, a field effect transistor, an electrode modifier, an electrode modifier for an organic field transistor, an actuator, or a transparent electrode.

The layering of the ink composition to form the HIL or HTL layer can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

In one embodiment, the HIL layer is thermally annealed. In one embodiment, the HIL layer is thermally annealed at temperature of about 25° C. to about 350° C., typically 150° C. to about 325° C. In one embodiment, the HIL layer is thermally annealed at temperature of about 25° C. to about 350° C., typically 150° C. to about 325° C., for about 3 to about 40 minutes, typically for about 15 to about 30 minutes.

In accordance with the present disclosure, an HIL or HTL can be prepared that can exhibit a transmittance (typically, with a substrate) of at least about 85%, typically at least about 90%, of light having a wavelength of about 380-800 nm. In an embodiment, the transmittance is at least about 90%.

In one embodiment, the HIL layer has a thickness of from about 5 nm to about 500 nm, typically from about 5 nm to about 150 nm, more typically from about 50 nm to 120 nm.

In an embodiment, the HIL layer exhibits a transmittance of at least about 90% and has a thickness of from about 5 nm to about 500 nm, typically from about 5 nm to about 150 nm, more typically from about 50 nm to 120 nm. In an embodiment, the HIL layer exhibits a transmittance (% T) of at least about 90% and has a thickness of from about 50 nm to 120 nm.

The inks, methods and processes, films, and devices according to the present disclosure are further illustrated by the following non-limiting examples.

### EXAMPLES

The components used in the following examples are summarized in the following Table 1.

TABLE 1
Summary of components

| S-poly(3- | |
|---|---|
| MEET) | Sulfonated poly(3-MEET) |
| TFE- | TFE/perfluoro-2-(vinyloxy)ethane-1-sulfonic acid |
| VEFS 1 | copolymer having equivalent weight of 676 g |
| | polymer/mol acid (available from Solvay as AQUIVION ® |
| | D66-20BS); n:m = 8:2 |
| CTFE- | CTFE/perfluoro-2-(vinyloxy)ethane-1-sulfonic acid |
| VEFS | copolymer having equivalent weight of 950 g |
| | polymer/mol acid (available from Solvay as |
| | AQUIVION ®) |
| S-PES | Sulfonated polyether sulfone with 30% & 35% acid |
| | loading (available from Konishi Chemical Ind. Co., Ltd); |
| | a:b = 0.9-0.7:0.1-0.3 |
| PHOST | Poly(4-hydroxystyrene) |
| TEA | triethylamine |
| PGME | Propylene glycol methyl ether (available from Dow |
| | Chemical Co. as DOWANOL ™ PM) |
| EG-ST | 20-21 wt % silica dispersion in ethylene glycol |
| | (ORGANOSILICASOL ™ EG-ST, available from Nissan |
| | Chemical) |
| TMU | Tetramethylurea |
| EG | Ethylene glycol |

### Example 1. Preparation of NQ Ink from an Initial Aqueous Mixture

An inventive non-aqueous (NQ) ink composition according to the present invention was prepared from an initial aqueous mixture. The initial aqueous mixture was prepared by mixing an aqueous dispersion of S-poly(3-MEET) (0.361% solids in water), an aqueous dispersion of TFE-VEFS 1 (20% solids in water), PHOST, and PGME. The resulting mixture is summarized in Table 2.

TABLE 2
Initial aqueous mixture, 3.7% total solids

| Component | Weight, g | Composition, % |
|---|---|---|
| S-poly(3-MEET) (0.361% solids in water) | 166.0 | 0.22 (solids) |
| TFE-VEFS 1 (20% solids in water) | 2.0 | 0.15 (solids) |
| PHOST | 9.0 | 3.33 (solids) |
| PGME | 91.0 | 33.71 |
| Water | 0.0 | 62.59 |

The solvents were then removed by rotary evaporation to yield 12.5 g of product.

The product was dispersed in a sufficient amount of dimethyl sulfoxide (DMSO) and filtered under pressure to yield a dispersion at 3.0% solids. TEA was then added to the dispersion to form a base ink, which is summarized in Table 3.

TABLE 3
Base ink, 3.0% total solids

| Component | Composition, % |
|---|---|
| S-poly(3-MEET) | 0.18 (solids) |
| TFE-VEFS 1 | 0.12 (solids) |
| PHOST | 2.70 (solids) |
| DMSO | 96.20 |
| TEA | 0.60 |

A 3 wt % dispersion of silica nanoparticles was prepared by mixing 1.5 grams of commercially-available 20-21 wt % silica dispersion in ethylene glycol (marketed as ORGANOSILICASOL™ EG-ST by Nissan Chemical) with 8.5 grams of DMSO. The resulting silica dispersion was added to the base ink with mechanical stirring and stirred for 1 hour to produce a clear blue ink. The ink was filtered through a 0.22 μm polypropylene filter. The inventive NQ inks prepared by this procedure are summarized in Table 4 below.

TABLE 4
Inventive NQ inks 1-3

| | NQ ink 1 | NQ ink 2 | NQ ink 3 |
|---|---|---|---|
| Base ink (g) | 3.75 | 2.50 | 3.15 |
| Silica dispersion (g) | 1.25 | 2.50 | 1.85 |

### Example 2. Preparation of NQ Ink from Stock Solutions

The inventive NQ ink compositions according to the present disclosure were prepared from stock solutions.

Stock Solution Preparation:

Rotary evaporation was used to isolate the solid components of an aqueous dispersion of S-poly(3-MEET). The dried solids were used to prepare a stock solution of S-poly(3-MEET) at 0.5% solids in DMSO with TEA. The solution was made by combining 0.05 g of dried S-poly(3-MEET) with 9.93 g of DMSO and 0.02 g of TEA. The mixture was stirred for 2 hours at 70° C., cooled to room temperature, and then filtered through a 0.22 μm polypropylene filter.

Rotary evaporation was used to isolate the solid components of an aqueous dispersion of TFE-VEFS 1 copolymer. The dried solids were used to prepare a stock solution of TFE-VEFS 1 copolymer at 3.0% solids in DMSO. The solution was made by combining 0.3 g of dried TFE-VEFS 1 copolymer with 9.70 g of DMSO. The mixture was stirred for 1 hour room temperature then filtered through a 0.22 μm polypropylene filter.

A stock solution of PHOST at 5.0% solids was prepared by combining 0.5 g of PHOST with 9.50 g of DMSO. The solution was stirred for 1 hour room temperature then filtered through a 0.22 μm polypropylene filter.

A stock solution of silica nanoparticles was prepared at 3.0% solids by combining 2.00 g of commercially-available 20-21 wt % silica dispersion in ethylene glycol (marketed as ORGANOSILICASOL™ EG-ST by Nissan Chemical) with 11.33 g of DMSO. The solution was stirred for 1 hour room temperature then filtered through a 0.22 μm polypropylene filter.

Ink Preparation from Stock Solutions:

An NQ ink, designated NQ ink 4, was prepared by adding 0.33 g of the TFE-VEFS 1 stock solution to 3.00 g of the S-poly(3-MEET) stock solution and the mixture was put under vortex for fifteen seconds. Once the solution was homogeneous, 3.25 g of the PHOST stock solution, 1.40 g of DMSO, and 0.06 g of TEA were added and put under vortex mixing for 15 seconds. Next, 2.08 g of silica nanoparticle stock solution was added. The resulting NQ ink was stirred for 1 hour at room temperature then filtered through a 0.22 μm polypropylene filter.

Similarly, another NQ ink, designated NQ ink 5, was prepared by adding 0.33 g of the TFE-VEFS 1 stock solution to 3.00 g of the S-poly(3-MEET) stock solution and the mixture was put under vortex for fifteen seconds. Once the solution was homogeneous, 2.00 g of the PHOST stock solution, 0.63 g of DMSO, and 0.06 g of TEA were added and put under vortex mixing for 15 seconds. Next, 4.17 g of silica nanoparticle stock solution was added. The resulting NQ ink was stirred for 1 hour at room temperature then filtered through a 0.22 μm polypropylene filter.

NQ inks 6-8 were prepared according to this procedure, except that the amounts of PHOST and SiO₂ nanoparticles were varied.

The compositions of NQ inks 4-8 are summarized in Table 5 below.

TABLE 5
Inventive NQ inks 4-8

| | NQ | NQ | NQ | NQ | NQ |
|---|---|---|---|---|---|
| | ink 4 | ink 5 | ink 6 | ink 7 | ink 8 |
| Component | wt % | wt % | wt % | wt % | wt % |
| S-poly(3-MEET) | 0.15 | 0.15 | 0.15 | 0.15 | 0.15 |
| | (solids) | (solids) | (solids) | (solids) | (solids) |
| TFE-VEFS 1 | 0.10 | 0.10 | 0.10 | 0.10 | 0.10 |
| | (solids) | (solids) | (solids) | (solids) | (solids) |
| PHOST | 1.62 | 1.00 | 2.02 | 1.82 | 1.57 |
| | (solids) | (solids) | (solids) | (solids) | (solids) |
| Silica nanoparticles | 0.63 | 1.25 | 0.23 | 0.43 | 0.68 |
| DMSO | 96.90 | 96.90 | 96.90 | 96.90 | 96.90 |
| TEA | 0.60 | 0.60 | 0.60 | 0.60 | 0.60 |

### Example 3. Preparation of NQ Ink from Solid S-Poly(3-MEET) Amine Adduct

S-poly(3-MEET) amine adduct was prepared by mixing 500 g of an aqueous dispersion of S-poly(3-MEET) (0.598% solids in water), with 0.858 g of triethylamine. The resulting mixture was rotary-evaporated to dryness, and then further dried in a vacuum oven at 50° C. overnight. The product was isolated as 3.8 g of black powder.

The NQ ink was prepared by combining 0.087 g of solid S-poly(3-MEET) amine adduct and 0.64 g of PHOST with 6.13 g of ethylene glycol and 0.12 g of triethyl amine. This combination was mixed for 1 hour in a vial on a shaker at 70° C. To the resulting dispersion, 4.50 g of CTFE-VEFS (1% solids in ethylene glycol) was added and mixed for 1 hour on a shaker at 70° C. Next, tetramethyl urea (3.53 g) was added and shaken at 70° C. for 1 hour to produce a clear dark blue ink at 5% solids. The ink was filtered through a 0.22 μm polypropylene filter.

The resulting ink composition, NQ ink 9, is summarized in Table 6.

TABLE 6
NQ ink 9 (5% total solids)

| Component | Weight, g | Composition, % |
|---|---|---|
| S-poly(3-MEET) amine adduct | 0.087 | 0.45 (solids) |
| CTFE-VEFS (1% solids in EG) | 4.50 | 0.30 (solids) |
| PHOST | 0.64 | 4.25 (solids) |
| TEA | 0.12 | 0.95 |
| EG | 6.13 | 70.54 |
| TMU | 3.53 | 23.51 |

### Example 4. Preparation of NQ Ink from Solid S-Poly(3-MEET) Amine Adduct Containing Silica Nanoparticles

A non-aqueous (NQ) ink composition was prepared from the solid S-poly(3-MEET) amine adduct of Example 3. The NQ ink was prepared by combining 0.015 g of solid S-poly(3-MEET) amine adduct with 5.79 g of ethylene glycol and 0.10 g of triethyl amine. This combination was mixed for 1 hour in a vial on a shaker at 70° C. To the resulting dispersion, 0.80 g of CTFE-VEFS (1% solids in ethylene glycol) was added and mixed for 1 hour on a shaker at 70° C. Next, 0.88 g of ORGANOSILICASOL™ EG-ST was added and mixed for 10 minutes on a shaker at 70° C. Tetramethyl urea, 2.43 g, was added and shaken at 70° C. for 1 hour to produces a clear dark blue ink at 2% solids. The ink was filtered through a 0.22 μm polypropylene filter.

The resulting ink composition, NQ ink 10, is summarized in Table 7.

TABLE 7
NQ ink 10 (2% total solids)

| Component | Weight, g | Composition, % |
|---|---|---|
| S-poly(3-MEET) amine adduct | 0.015 | 0.12 (solids) |
| CTFE-VEFS (1% solids in EG) | 0.800 | 0.08 (solids) |
| EG-ST | 0.88 | 1.80 (solids) |
| TEA | 0.10 | 0.98 |
| EG | 5.79 | 72.76 |
| TMU | 2.43 | 24.26 |

### Example 5. Preparation of NQ Ink from Solid S-Poly(3-MEET) Amine Adduct and S-PES Containing Silica Nanoparticles

The NQ ink was prepared by combining 0.116 g of solid S-poly(3-MEET) amine adduct with 0.060 g S-PES, 8.25 g of ethylene glycol and 0.12 g of triethyl amine. This combination was mixed for 1 hour in a vial on a shaker at 70° C. To the resulting dispersion, 2.93 g of EG-ST was added and mixed for 1 hour on a shaker at 70° C. Next, tetramethyl urea (3.53 g) was added and shaken at 70° C. for 1 hour to produce a clear dark blue ink at 5% solids. The ink was filtered through a 0.22 μm polypropylene filter.

The resulting ink composition, NQ ink 11, is summarized in Table 8.

TABLE 8
NQ ink 11 (5% total solids)

| Component | Weight, g | Composition, % |
|---|---|---|
| S-poly(3-MEET) amine adduct | 0.116 | 0.60 (solids) |
| S-PES | 0.060 | 0.40 (solids) |
| EG-ST | 2.93 | 4.00 (solids) |
| TEA | 0.12 | 0.95 |
| EG | 8.25 | 70.54 |
| TMU | 3.53 | 23.51 |

### Example 6. Preparation of NQ Ink from Solid S-Poly(3-MEET) Amine Adduct and S-PES

A non-aqueous (NQ) ink composition was prepared from the solid S-poly(3-MEET) amine adduct of Example 3. The NQ ink was prepared by combining 0.046 g of solid S-poly(3-MEET) amine adduct with 0.474 g PHOST, 0.090 g of S-PES, 8.47 g of ethylene glycol and 0.10 g of triethyl amine. This combination was mixed for 1 hour in a vial on a shaker at 70° C. To the resulting dispersion, tetramethyl urea, 2.43 g, was added and shaken at 70° C. for 1 hour to produce a clear dark blue ink at 2% solids. The ink was filtered through a 0.22 μm polypropylene filter.

The resulting ink composition, NQ ink 12, is summarized in Table 9.

TABLE 9
NQ ink 12 (5% total solids)

| Component | Weight, g | Composition, % |
|---|---|---|
| S-poly(3-MEET) amine adduct | 0.046 | 0.30 (solids) |
| S-PES | 0.090 | 0.75 (solids) |
| PHOST | 0.474 | 3.95 (solids) |
| TEA | 0.10 | 0.95 |
| EG | 8.47 | 70.54 |
| TMU | 2.83 | 23.51 |

### Example 7. Film Formation and Properties

Films were formed by spin-coating using a Laurel spin coater at 3000 rpm for 90 seconds, and annealing on a hot plate at various temperatures for 30 minutes.

The coating thickness was measured by a profilometer (Veeco Instruments, Model Dektak 8000) and reported as the average of three readings.

Films formed from NQ inks 4-8 of Example 2 at various anneal temperatures (250° C., 275° C., and 300° C.). As a comparative example, films free of SiO₂ nanoparticles were made from the base ink described in Table 3 at various anneal temperatures, including 250° C., 275° C., and 300° C. The wt % of SiO₂ nanoparticles in the respective films are summarized in Table 6.

TABLE 10

| | Wt. % SiO₂ |
|---|---|
| NQ Ink | nanoparticles in film |
| Base ink | 0 |
| 4 | 25 |
| 5 | 50 |
| 6 | 9 |
| 7 | 17 |
| 8 | 27 |

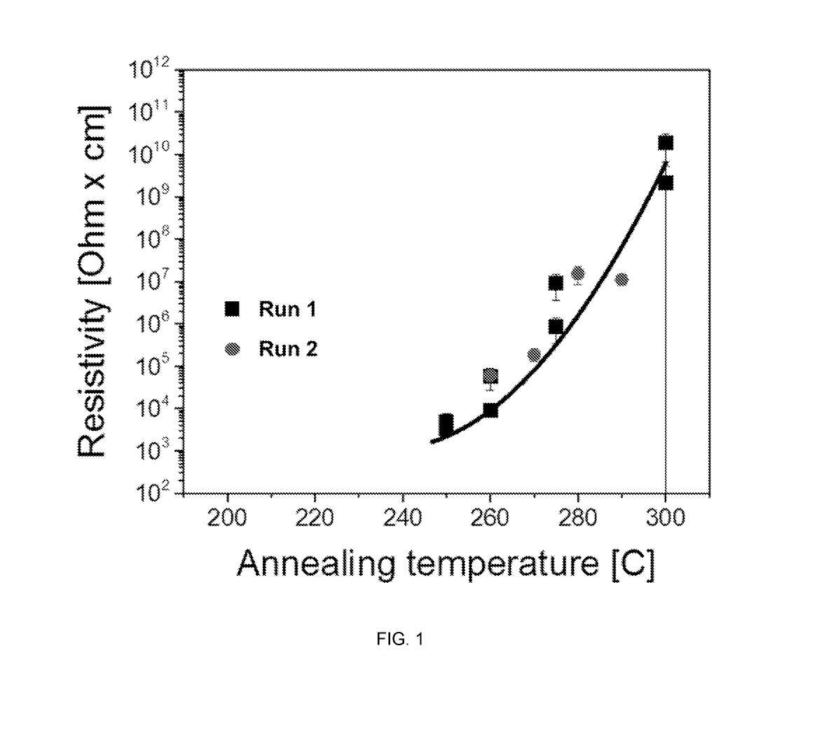

FIG. 1 shows the resistivity of films made from the base ink, which is free of SiO₂ nanoparticles, as a function of annealing temperature.

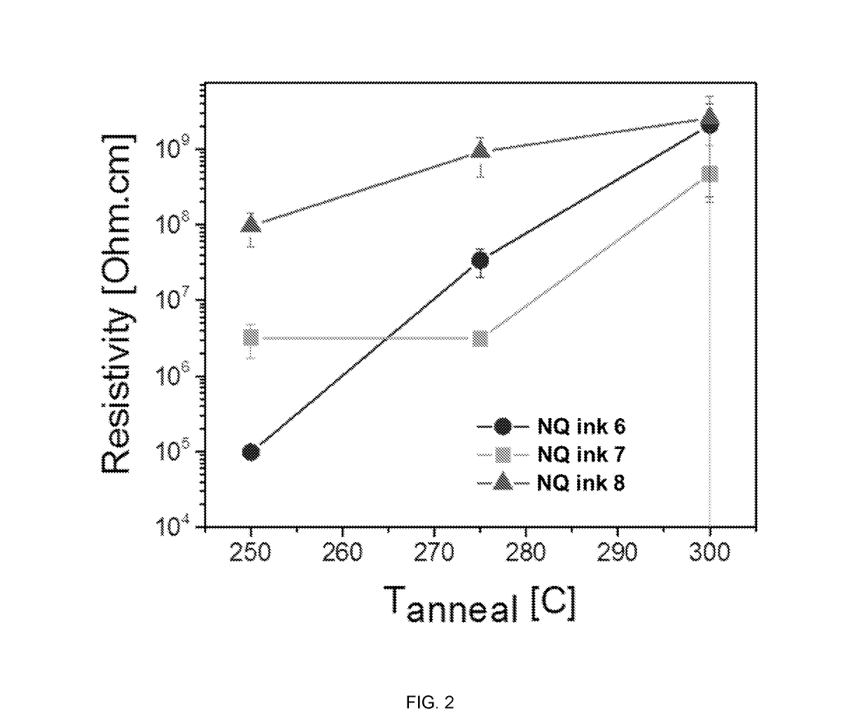

FIG. 2 shows the resistivities of films made from inventive NQ inks 6-8 as a function of annealing temperature. It can be seen that the resistivity of films made from the inventive NQ inks are higher than the resistivity of films made from the base ink that does not contain SiO₂ nanoparticles, especially at anneal temperatures of at least 250° C. Thus, the inventive NQ inks described herein provide the ability to tune the resistivity of films suitable for use in organic electronic applications, for example, in the formation of HILs.

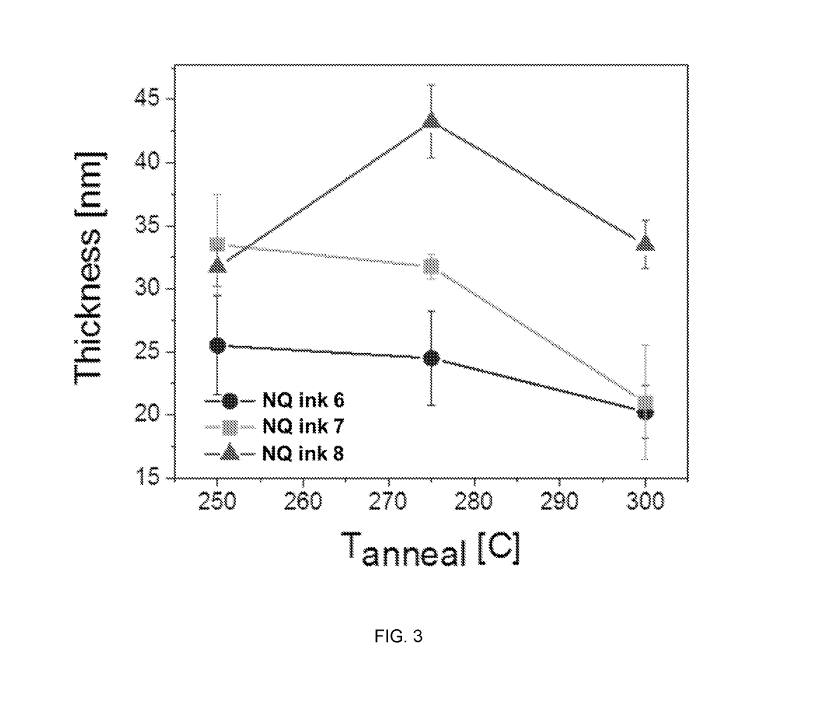

FIG. 3 shows the thickness of the films made from inventive NQ inks 6-8 as a function of annealing temperature.

### Example 8. Unipolar Device Fabrication and Testing

The unipolar, single charge-carrier devices described herein were fabricated on indium tin oxide (ITO) surfaces deposited on glass substrates. The ITO surface was pre-patterned to define the pixel area of 0.05 cm². Before depositing an HIL ink composition on the substrates, pre-conditioning of the substrates was performed. The device substrates were first cleaned by ultrasonication in various solutions or solvents. The device substrates were ultrasonicated in a dilute soap solution, followed by distilled water, then acetone, and then isopropanol, each for about 20 minutes. The substrates were dried under nitrogen flow. Subsequently, the device substrates were then transferred to a vacuum oven set at 120° C. and kept under partial vacuum (with nitrogen purging) until ready for use. The device substrates were treated in a UV-Ozone chamber operating at 300 W for 20 minutes immediately prior to use.

Before the HIL ink composition is deposited onto an ITO surface, filtering of the ink composition through a PP 0.22-μm filter is performed.

The HIL was formed on the device substrate by spin coating. Generally, the thickness of the HIL after spin-coating onto the ITO-patterned substrates is determined by several parameters such as spin speed, spin time, substrate size, quality of the substrate surface, and the design of the spin-coater. General rules for obtaining certain layer thickness are known to those of ordinary skill in the art. After spin-coating, the HIL layer was dried on a hot plate.

The substrates comprising the inventive HIL layers were then transferred to a vacuum chamber where the remaining layers of the device stack were deposited by means of physical vapor deposition.

All steps in the coating and drying process are done under an inert atmosphere, unless otherwise stated.

N,N′-bis(1-naphtalenyl)-N,N′-bis(phenyl)benzidine (NPB) was deposited as a hole transport layer on top of the HIL followed by a gold (Au) or aluminum (Al) cathode. The typical device stack, including target film thickness, for the unipolar device, is ITO (220 nm)/HIL (100 nm)/NPB (150 nm)/Al (100 nm). This is a unipolar device wherein the hole-only injection efficiency of the HIL into the HTL is studied.

The unipolar device comprises pixels on a glass substrate whose electrodes extended outside the encapsulated area of the device which contain the light emitting portion of the pixels. The typical area of each pixel is 0.05 cm². The electrodes were contacted with a current source meter such as a Keithley 2400 source meter with a bias applied to the ITO electrode while the gold or aluminum electrode was earthed. This results in only positively charged carriers (holes) being injected into the device (hole-only device or HOD).

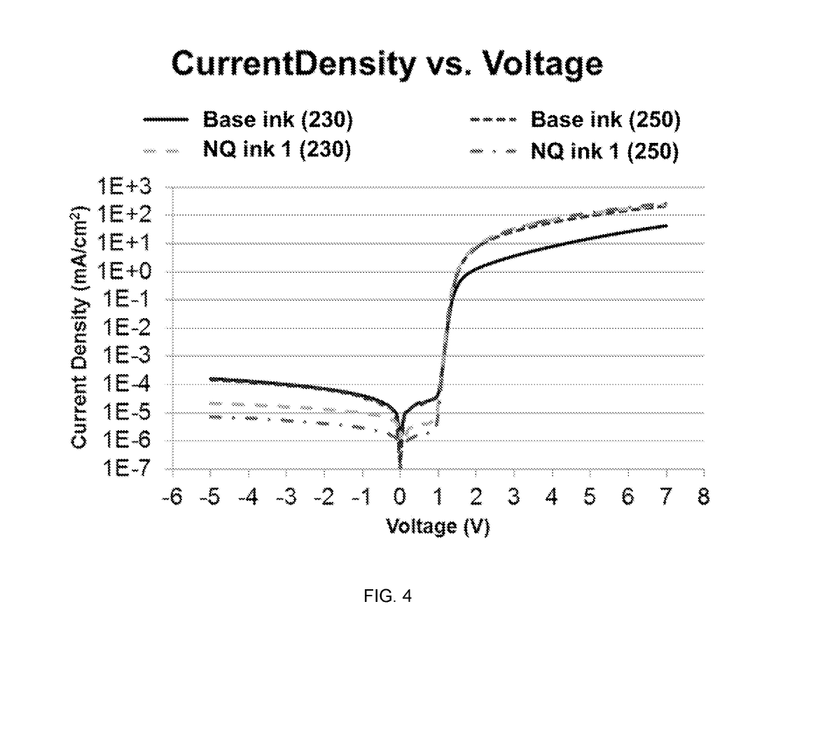

FIG. 4 shows thermal stability improvement in an HIL made from NQ ink 1 (DMSO based with SiO₂) vs. Base ink (DMSO based ink without SiO₂).

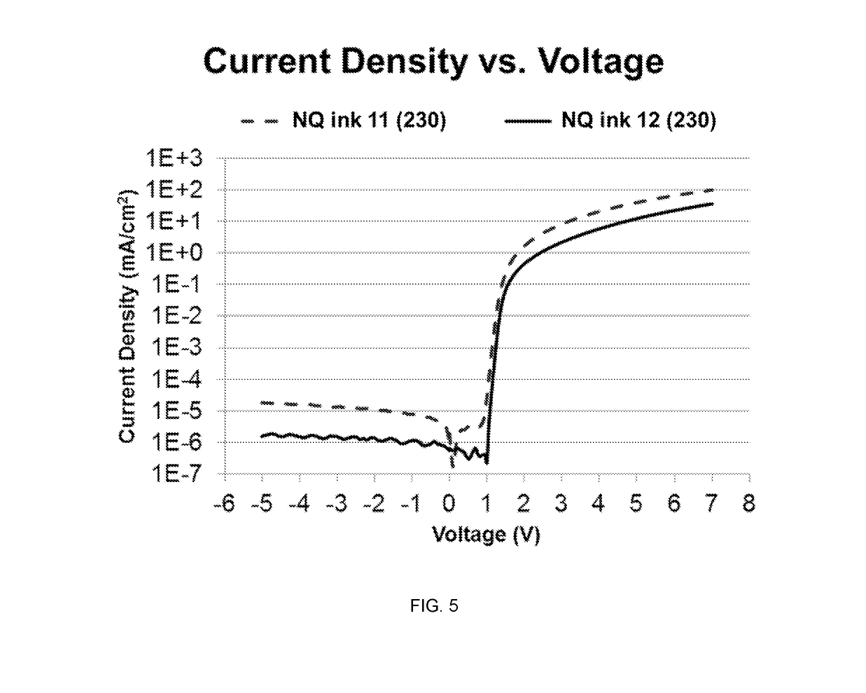

FIG. 5 shows voltage (hole injection) improvement in an HIL made from NQ ink 11 vs. an HIL made from NQ ink 12.

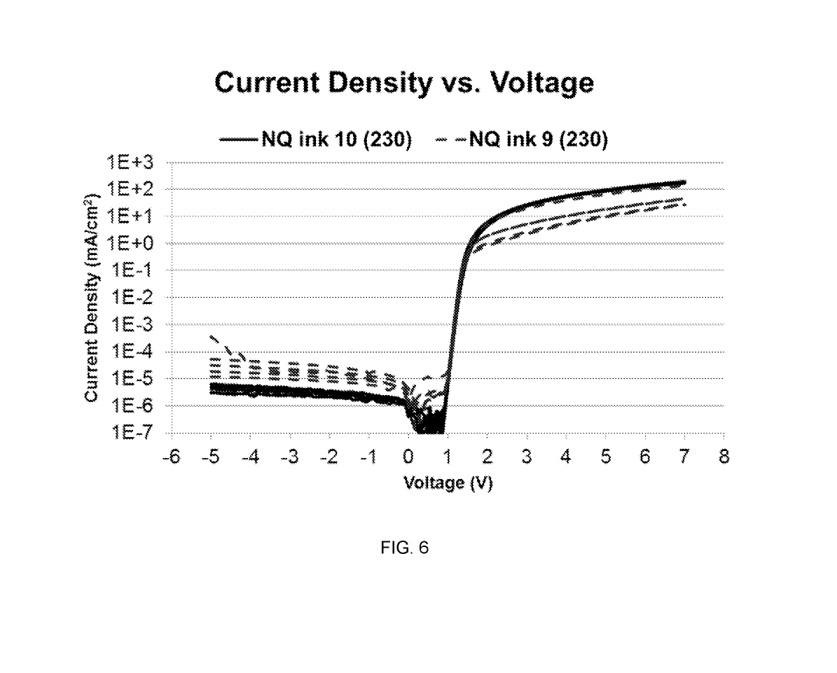

FIG. 6 shows plate-to-plate result variability improvement in an HIL made from NQ ink 10 vs. an HIL made from NQ ink 9.

The HILs showed improvements in thermal stability, hole injection, and plate-to-plate result variability.

What is claimed is:

1. A non-aqueous ink composition comprising:
(a) a polythiophene comprising a repeating unit complying with formula (I) 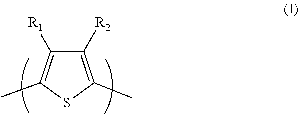
wherein R₁ and R₂ are each, independently, H, alkyl, fluoroalkyl, alkoxy, aryloxy, or —O—[Z—O]ₚ—Rₑ;
wherein
Z is an optionally halogenated hydrocarbylene group,
p is equal to or greater than 1, and
Rₑ is H, alkyl, fluoroalkyl, or aryl;
(b) one or more metalloid nanoparticles; and
(c) a liquid carrier comprising one or more organic solvents.

2. The non-aqueous ink composition according to claim 1, wherein R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d}, are each, independently, H, halogen, alkyl, fluoroalkyl, or aryl; Rₑ is H, alkyl, fluoroalkyl, or aryl; p is 1, 2, or 3; and R_{f} is alkyl, fluoroalkyl, or aryl.

3. The non-aqueous ink composition according to claim 1 or 2, wherein R₁ is H and R₂ is other than H.

4. The non-aqueous ink composition according to claim 1 or 2, wherein R₁ and R₂ are both other than H.

5. The non-aqueous ink composition according to claim 4, wherein R₁ and R₂ are each, independently, —O[C(RₐR_{b})—C(R_{c}R_{d})—O]ₚ—Rₑ, or —OR_{f}.

6. The non-aqueous ink composition according to claim 5, wherein R₁ and R₂ are both —O[C(RₐR_{b})—C(R_{c}R_{d})—O]ₚ—Rₑ.

7. The non-aqueous ink composition according to any one of claims 2-6, wherein each occurrence of Rₐ, R_{b}, R_{c}, and R_{d}, are each, independently, H, (C₁-C₈)alkyl, (C₁-C₈)fluoroalkyl, or phenyl; and Rₑ is (C₁-C₈)alkyl, (C₁-C₈)fluoroalkyl, or phenyl.

8. The non-aqueous ink composition according to any one of claims 1-7, wherein the polythiophene comprises a repeating unit selected from the group consisting of 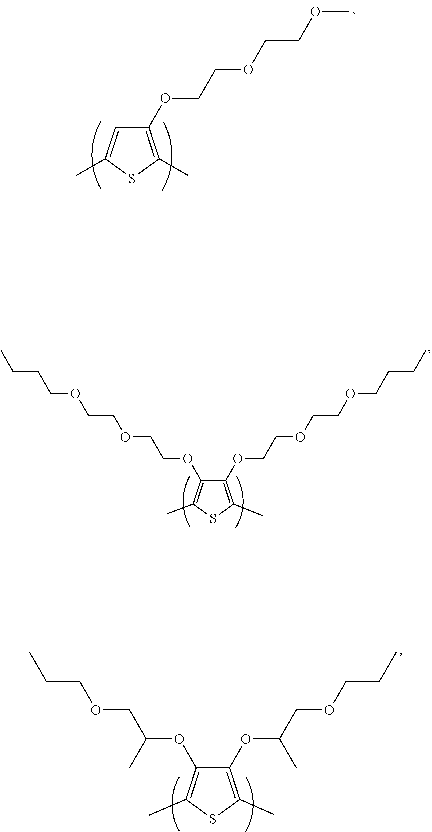
and combinations thereof.

9. The non-aqueous ink composition according to any one of claims 1-8, wherein the polythiophene is sulfonated.

10. The non-aqueous ink composition according to claim 9, wherein the polythiophene is sulfonated poly(3-MEET).

11. The non-aqueous ink composition according to any one of claims 1-10, wherein the polythiophene comprises repeating units complying with formula (I) in an amount of greater than 50% by weight, typically greater than 80% by weight, more typically greater than 90% by weight, even more typically greater than 95% by weight, based on the total weight of the repeating units.

12. The non-aqueous ink composition according to any one of claims 1-11, wherein the one or more metalloid nanoparticles comprise B₂O₃, B₂O, SiO₂, SiO, GeO₂, GeO, As₂O₄, As₂O₃, As₂O₅, Sb₂O₃, TeO₂, SnO₂, SnO, or mixtures thereof.

13. The non-aqueous ink composition according to claim 12, wherein the one or more metalloid nanoparticles comprise SiO₂.

14. The non-aqueous ink composition according to any one of claims 1-13, wherein the one or more metalloid nanoparticles comprise one or more organic capping groups.

15. The non-aqueous ink composition according to any one of claims 1-14, wherein the amount of the metalloid nanoparticles is from 1 wt. % to 98 wt. %, typically from about 2 wt. to about 95 wt. %, more typically from about 5 wt. % to about 90 wt. %, still more typically about 10 wt. % to about 90 wt. %, relative to the combined weight of the metalloid nanoparticles and the doped or undoped polythiophene.

16. The non-aqueous ink composition according to any one of claims 1-15, wherein the non-aqueous ink composition further comprises a synthetic polymer comprising one or more acidic groups.

17. The non-aqueous ink composition according to claim 16, wherein the synthetic polymer is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

18. The non-aqueous ink composition according to claim 17, wherein the polymeric acid comprises a repeating unit complying with formula (II) and a repeating unit complying with formula (III) 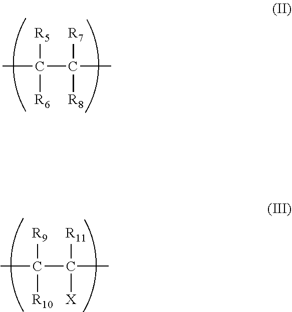
wherein
each occurrence of R₅, R₆, R₇, R₈, R₉, R₁₀, and R₁₁ is, independently, H, halogen, fluoroalkyl, or perfluoroalkyl; and
X is —[OC(RₕRᵢ)—C(RⱼRₖ)]_{q}—O—[CRₗRₘ]_{z}—SO₃H,
wherein each occurrence of Rₕ, Rᵢ, Rⱼ, Rₖ, Rₗ and Rₘ is, independently,
H, halogen, fluoroalkyl, or perfluoroalkyl;
q is 0 to 10; and
z is 1-5.

19. The non-aqueous ink composition according to claim 16, wherein the synthetic polymer is a polyether sulfone comprising one or more repeating units comprising at least one sulfonic acid (—SO₃H) moiety.

20. The non-aqueous ink composition according to claim 19, wherein the polyether sulfone comprises a repeating unit complying with formula (IV) 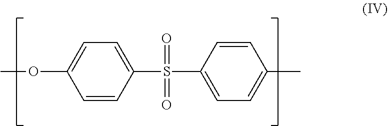
and a repeating unit selected from the group consisting of a repeating unit complying with formula (V) and a repeating unit complying with formula (VI) 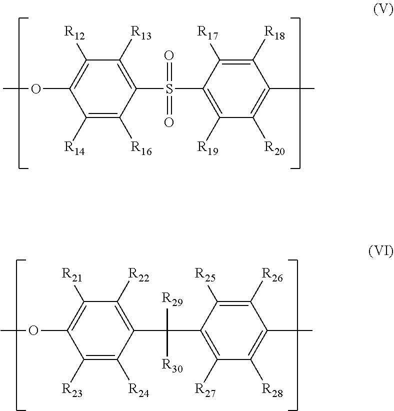
wherein R₁₂-R₂₀ are each, independently, H, halogen, alkyl, or SO₃H, provided that at least one of R₁₂-R₂₀ is SO₃H; and
wherein R₂₁-R₂₈ are each, independently, H, halogen, alkyl, or SO₃H, provided that at least one of R₂₁-R₂₈ is SO₃H, and
R₂₉ and R₃₀ are each H or alkyl.

21. The non-aqueous ink composition according to any one of claims 1-20, wherein the non-aqueous ink composition further comprises a poly(styrene) or poly(styrene) derivative.

22. The non-aqueous ink composition according to any one of claims 1-21, wherein the non-aqueous ink composition further comprises one or more amine compounds.

23. A process for forming a hole-carrying film, the process comprising:
1) coating a substrate with a non-aqueous ink composition according to any one of claims 1-22; and
2) annealing the coating on the substrate, thereby forming the hole-carrying film.

24. The process according to claim 23, wherein the annealing temperature is from about 25° C. to about 350° C., typically from about 150° C. to about 325° C., more typically from about 200° C. to about 300° C., still more typically from about 230° C. to about 300° C.

25. A hole-carrying film formed by the process according to claim 23 or 24.

26. The hole-carrying film according to claim 25, wherein the film has transmittance of at least 85%, typically at least 90%, of light having a wavelength of about 380-800 nm.

27. The hole-carrying film according to claim 25 or 26, wherein the film has a thickness of from about 5 nm to about 500 nm, typically from about 5 nm to about 150 nm, more typically from about 50 nm to 120 nm.

28. A device comprising the hole-carrying film according to any one of claims 25-27, wherein the device is an OLED, OPV, transistor, capacitor, sensor, transducer, drug release device, electrochromic device, or battery device.
